(19) United States
(12) Patent Application Publication
(10) Pub. No.: US 2023/0154318 A1
(43) Pub. Date: May 18, 2023

(54) SPIN DEFECT TRAFFIC SENSORS

(71) Applicant: X Development LLC, Mountain View, CA (US)

(72) Inventors: Christian Thieu Nguyen, San Diego, CA (US); Stefan Bogdanovic, Mountain View, CA (US)

(21) Appl. No.: 17/527,895

(22) Filed: Nov. 16, 2021

(51) Int. Cl. G08G 1/04; G01R 33/12; G01R 33/032

(52) U.S. Cl. CPC G08G 1/04; G01R 33/032; G01R 33/1284

(57) ABSTRACT

A traffic monitoring system includes an electron spin defect magnetometer in a vicinity of a roadway, the electron spin defect magnetometer configured to detect magnetic field signals induced by transit entities in the vicinity of the roadway. The electron spin defect magnetometer includes an electron spin defect body including a plurality of lattice point defects, an optical source arranged to excite the plurality of lattice point defects, and a photodetector arranged to receive photoluminescence emitted by the plurality of lattice point defects.

### BACKGROUND

Various sensors are available that rely on classical physical phenomena for detecting properties such as electric or magnetic fields. These sensors include traffic sensors. In certain cases, traffic sensors are limited by one or more of their sensitivity, dynamic range, form factor, and/or road positioning.

The most common magnetic traffic sensor currently in use is the inductive loop detector. Inductive loop detectors are conductive loops placed below a roadway, e.g., embedded in road pavement. A small oscillating current is applied to the loop. When a vehicle passes over the loop, magnetic field effects from the vehicle (including, for example, an increase in loop inductance due to ferrous metal in the vehicle, and/or a decrease in loop inductance due to eddy currents in peripheral metal of the vehicle) modify the loop impedance, and the modification is detected by a sensor coupled to the loop. Other types of magnetic field-based traffic sensors, such as magneto-resistive sensors, are typically installed in a similar fashion, for example, in bores below a road surface. Detection zones for inductive loop and magneto-resistive sensors are typically on the order of several feet, which dictates their sub-surface placement.

### SUMMARY

The present disclosure relates to traffic sensing using spin defect magnetometers. In some examples, the disclosure describes a traffic monitoring system. The traffic monitoring system includes an electron spin defect magnetometer in a vicinity of a roadway, the electron spin defect magnetometer configured to detect magnetic field signals induced by transit entities in the vicinity of the roadway. The electron spin defect magnetometer includes an electron spin defect body including a plurality of lattice point defects, an optical source arranged to excite the plurality of lattice point defects, and a photodetector arranged to receive photoluminescence emitted by the plurality of lattice point defects.

Implementations of this and other traffic monitoring systems and devices thereof can have any one or more of at least the following characteristics, and/or other characteristics as described herein.

In some implementations, the electron spin defect magnetometer is fixed in an elevated position with respect to the roadway.

In some implementations, the traffic monitoring system includes a computer system coupled to the electron spin defect magnetometer. The computer system is configured to perform operations that include receiving, from the electron spin defect magnetometer, a signal indicative of a magnetic field to which the electron spin defect magnetometer is exposed, and detecting a presence of a transit entity based on the signal.

In some implementations, the signal includes a signal of photoluminescence detected in the electron spin defect magnetometer.

In some implementations, the operations include determining, based on the signal, a magnetic field direction of the magnetic field to which the electron spin defect magnetometer is exposed.

In some implementations, the operations include identifying, based on the signal, at least one of a type of the transit entity, a size of the transit entity, or a trajectory of the transit entity.

In some implementations, the transit entity includes a ground transportation vehicle or a pedestrian.

In some implementations, identifying at least one of the type, the size, or the trajectory of the transit entity includes inputting the signal into a trained machine learning model that outputs an indication of at least one of the type, the size, or the trajectory.

In some implementations, identifying at least one of the type, the size, or the trajectory of the transit entity includes extracting, from the signal, a magnetic field signature; and comparing the magnetic field signature to a plurality of predefined magnetic field signatures.

In some implementations, the operations include filtering out a frequency component of the signal.

In some implementations, the computer system is located in the vicinity of the roadway.

In some implementations, the traffic monitoring system includes a plurality of electron spin defect magnetometers in the vicinity of the roadway, including the electron spin defect magnetometer, and a computer system configured to perform operations. The operations include receiving, from the plurality of electron spin defect magnetometers, a corresponding plurality of signals indicative of respective magnetic fields to which the electron spin defect magnetometers are exposed, and determining a location of a transit entity based on signals from at least two electron spin defect magnetometers of the plurality of electron spin defect magnetometers.

In some implementations, determining the location of the transit entity includes performing a triangulation process based on the signals from the at least two electron spin defect magnetometers.

In some implementations, the operations include extracting a first magnetic field signature from a first signal of the plurality of signals, extracting a second magnetic field signature from a second signal of the plurality of signals, and determining that the first magnetic field signature and the second magnetic field signature are caused by a same transit entity in the vicinity of the roadway.

In some implementations, the optical source is configured to excite the plurality of lattice point defects with light of a first wavelength that excites the plurality of lattice point defects from a ground state to an excited state, and the photoluminescence emitted by the plurality of lattice point defects includes light of a second wavelength that is different from the first wavelength.

In some implementations, the electron spin defect magnetometer includes a magnet configured to apply a magnetic field to the electron spin defect body.

In some implementations, the electron spin defect magnetometer includes a microwave field transmitter configured to apply a microwave field to the electron spin defect body.

Implementations according to the present disclosure may provide one or more of at least the following advantages. In some implementations, detection sensitivity can be improved. In some implementations, detection dynamic range can be improved. In some implementations, sensor placement can be made more flexible, including mounted sensors and sensors that are further from detected vehicles. In some implementations, detection can be improved in the presence of various weather conditions and signal interference. In some implementations, sensors can be made smaller and/or at less expense. Measurements by the sensors can be analyzed to improve traffic flow, predict crashes, and otherwise analyze traffic patterns.

In some examples, this disclosure describes methods. For example, this disclosure describes a method in which an electron spin defect magnetometer is operated in a vicinity of a roadway to obtain a signal indicative of a magnetic field to which an electron spin defect body of the electron spin defect magnetometer is exposed. A presence of a transit entity is detected based on the signal.

Implementations of this and other methods can have any one or more of at least the following characteristics, and/or other characteristics as described herein.

In some implementations, the method includes determining, based on the signal, a magnetic field direction of the magnetic field.

In some implementations, the method includes identifying, based on the signal, at least one of a type of the transit entity, a size of the transit entity, or a trajectory of the transit entity.

In some implementations, the transit entity includes a ground transportation vehicle or a pedestrian.

In some implementations, identifying at least one of the type, the size, or the trajectory of the transit entity includes inputting the signal into a trained machine learning model that outputs an indication of at least one of the type, the size, or the trajectory.

In some implementations, identifying at least one of the type, the size, or the trajectory of the transit entity includes extracting, from the signal, a magnetic field signature; and comparing the magnetic field signature to a plurality of predefined magnetic field signatures.

In some implementations, the method includes filtering out a frequency component of the signal.

In some implementations, the signal is a first signal, and the method includes operating a second electron spin defect magnetometer in the vicinity of the roadway to obtain a second signal indicative of a second magnetic field to which an electron spin defect body of the second electron spin defect magnetometer is exposed, and determining a location of a transit entity based on the first signal and based on the second signal.

In some implementations, determining the location of the transit entity includes performing a triangulation process based on the first signal and based on the second signal.

In some implementations, the method includes extracting a first magnetic field signature from the first signal, extracting a second magnetic field signature from the second signal, and determining that the first magnetic field signature and the second magnetic field signature are caused by a same transit entity in the vicinity of the roadway.

In some implementations, operating the electron spin defect magnetometer includes exciting a plurality of lattice point defects in the electron spin defect body.

In some implementations, operating the electron spin defect magnetometer includes measuring photoluminescence emitted by the electron spin defect body.

The details of one or more embodiments are set forth in the accompanying drawings and the description below. Other features, objects, and advantages of the invention will be apparent from the description and drawings, and from the claims.

### BRIEF DESCRIPTION OF THE DRAWINGS

FIG. 1 is a diagram that illustrates an exemplary energy level scheme for a nitrogen-vacancy defect.

FIG. 2 is a plot of exemplary photoluminescence intensity versus applied microwave frequency.

FIG. 3 is a diagram that illustrates an exemplary process for performing electron spin defect based magnetometry to detect an AC magnetic field.

FIG. 4 is a diagram that illustrates an exemplary electron spin defect magnetometer.

FIG. 5 is a diagram that illustrates an example road system including sensing components.

FIG. 6 is a plot of an exemplary magnetic field signature.

FIGS. 7A-7B are diagrams showing training and use of an exemplary model.

FIG. 8 is a diagram that illustrates an example road system including sensing components.

FIG. 9 is plots of two exemplary magnetic field signals.

FIG. 10A is a diagram that illustrates an isotropic magnetic field sensor.

FIG. 10B is a diagram that illustrates an anisotropic magnetic field sensor.

FIG. 10C is a diagram that illustrates a system of multiple anisotropic magnetic field sensors.

FIG. 11 is a diagram of an example distributed traffic system.

FIG. 12 is a diagram that illustrates an example detection process.

FIG. 13 is a diagram of an example computer system.

### DETAILED DESCRIPTION

The present disclosure relates to traffic sensors that exploit electron spin defect-based magnetometry. In particular, in some implementations, the present disclosure relates to the use of roadway-adjacent electron spin defect bodies to sense magnetic fields and, based on the magnetic fields, classify and spatially locate transit entities such as cars, trucks, bicycles, pedestrians, and accessories. Zeeman shifts of electron spin sublevels established by the presence of atomic defects in one or more electron spin defect bodies are monitored in order to sense local magnetic fields to which the electron spin defect bodies are exposed. Sensed magnetic fields can be correlated across multiple electron spin defect bodies for location determination. The sensed fields include magnetic field signatures that can be analyzed for transit entity characteristics, such as transit entity type, size, location, and/or velocity.

More specifically, electron spin defect-based magnetometers include quantum sensors that leverage the occurrence of an electronic spin defect in a solid state lattice, where the spin can be both initialized and read out optically. In certain implementations, the defect may arise as an atomic-level vacancy in a lattice structure (sometimes called a “defect body”), such as a vacancy occurring near a nitrogen atom substituted in place of a carbon atom within diamond. Accordingly, a single spin defect center, as an atom-scale defect, can be used to detect magnetic fields with nanometer spatial resolution, while an ensemble of uncorrelated spin defects can be used with spatial resolution given by the ensemble size (e.g., on the order of microns) typically with an improvement in sensitivity given by √N, where N is the number of spin defects. Moreover, in some implementations, electron spin defect-based magnetometers may exhibit relatively long coherence times, such as times approaching 1 second or more. Additionally, electron spin defect-based magnetometers can be operated at room temperature and, in certain cases, within relatively compact structures, allow for portability and reduction in magnetometer costs, which can be advantageous in health related applications such as measuring magnetic fields emanating from the heart, or in distributed sensing applications such as traffic sensing in which useful data depends on an (in some cases large) ensemble of coupled, rugged, and low-cost devices.

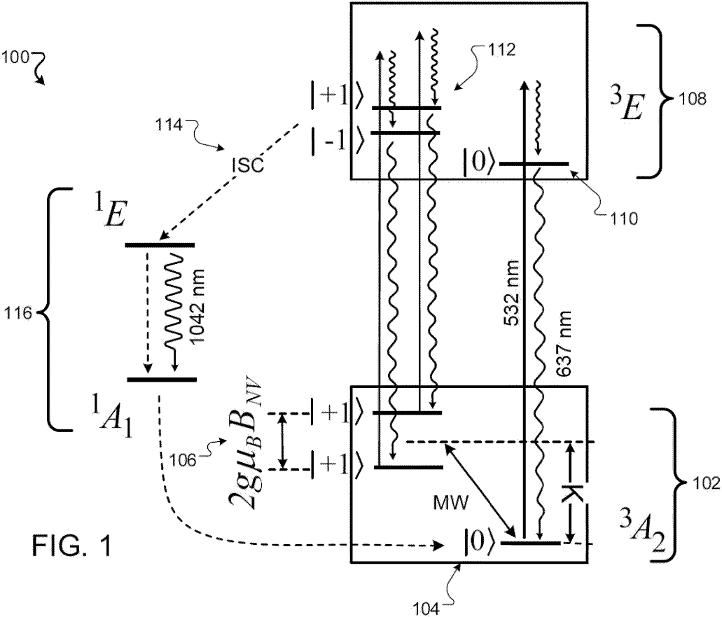

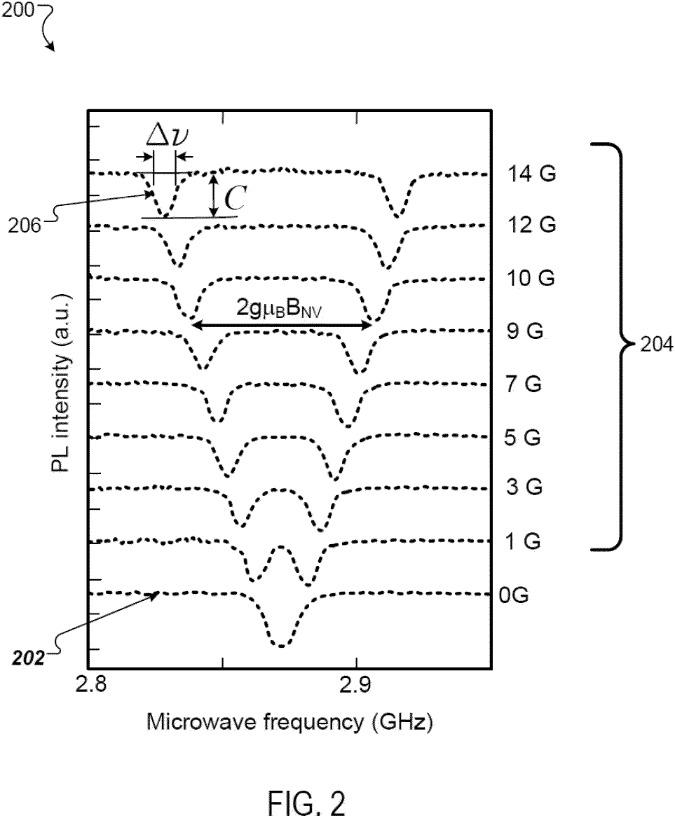

A brief description of electron spin defect-based magnetometry will be described with reference to FIGS. 1-2 and in particular with respect to nitrogen vacancy (NV) magnetometry, though the techniques and devices disclosed herein can be applicable to other materials, including other types of electron spin defects, as well. An NV center is a defect in a diamond lattice (defect body) that contains a substitutional nitrogen atom in place of carbon, adjacent to a vacancy in the diamond lattice. The negatively-charged state of the defect provides a spin triplet ground level which can be initialized, coherently manipulated with long coherence time, and readout using optical means. FIG. 1 is a schematic that illustrates an energy level scheme 100 for an NV defect. The NV defect behaves as an artificial atom within the diamond lattice that exhibits a broadband photoluminescence emission with a zero phonon line at 1.945 eV or λ_{PL} = 637 nm. Moreover, the ground level 102 of the NV defect is a spin triplet state, having spin sub-levels of the mₛ = 0 state 104 and the mₛ = +/-1 states 106, separated by K = 2.87 GHz in the absence of a magnetic field. The defect can be optically excited to an excited level 108, which also is a spin triplet having an mₛ = 0 state 110 and mₛ = +/-1 states 112. Once optically excited into the excited level 108, the NV defect can relax primarily through one of two mechanisms: a) through a radiative transition and phonon relaxation, thus producing a broadband red photoluminescence; or b) through a secondary path 114 that involves non-radiative intersystem crossing to singlet states 116.

The decay path branching ratios from the excited state manifold back to the ground state manifold depends on its initial spin sublevel projection. Specifically, if the electron spin began in the mₛ = +/-1 states, there is approximately a 30% chance for the spin to decay non-radiatively through the secondary path 114, down to the mₛ = 0 state. The population of the spin sublevels can be manipulated by the application of a resonant microwave field to the diamond. Specifically, at a particular microwave frequency corresponding to the transition energy cost between the 0 and +/-1 states, transitions occur between those sublevels, resulting in a change in the level of photoluminescence of the system. In particular, if the spin is initialized into the mₛ = 0 state, and the population is transferred to one of the +/-1 states by the resonant microwave drive, the photoluminescence rate upon subsequent optical illumination will decrease.

This drop in photoluminescence can be observed by sweeping the microwave frequency, as depicted in the bottom-most photoluminescence (PL) intensity line 202 shown in FIG. 2, which is a plot of PL intensity versus applied microwave frequency. Upon applying a magnetic field in the vicinity of the NV defect, however, the degeneracy of the mₛ = +/- 1 spin sublevels is lifted by the Zeeman effect, leading to the appearance of two electron spin resonance (ESR) transitions, corresponding to dips in the PL spectrum (see upper PL lines 204 in FIG. 2). The value Δv corresponds to the ESR linewidth, typically on the order of 1 MHz, and the value C is the ESR contrast, typically on the order of a few percent. To detect small magnetic fields, the NV transitions can be driven at the point of maximum slope (see, e.g., 206 in FIG. 2). At this point of maximum slope, a time-domain change in the photoluminescence can be detected, from which a time-domain change in magnetic field can be derived. The signal can be expressed as (∂I₀/∂B) x δB x Δt, where I₀ is the NV defect PL rate, δB is the infinitesimal magnetic field variation, and Δt is the measurement duration, much smaller than the timescale on which the magnetic field changes A single NV defect therefore can serve as a magnetic field sensor with an atomic-sized detection volume. To improve sensitivity, a collective response of an ensemble of NV defects can be detected, such that the collected PL signal is magnified by the number N of the sensing spins, and therefore the shot-noise-limited magnetic field sensitivity is improvedlas by a factor of ⅟√N.

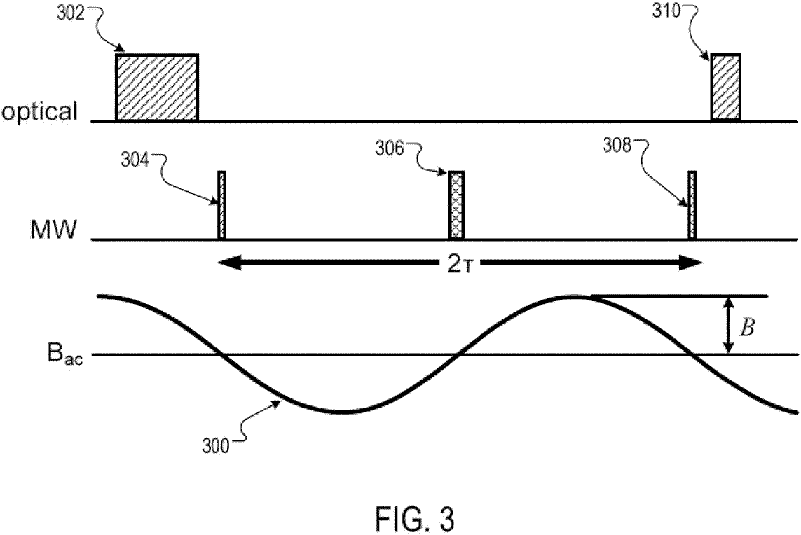

Magnetic field sensitivity can further be improved if the magnetic field to be measured is periodic in time (e.g., an AC field). The improvement in sensitivity with a classical AC field is a result of a prolongation of the NV spin coherence that can be achieved through dynamical decoupling of the central spin from its environment. To avoid broadening of the ESR linewidth caused by the readout process and the driving microwave field, the spin manipulation, spin readout and phase accumulation (magnetic field measurement) can be separated in time. To do so, a series of microwave pulses are applied in sequence to the NV defect (or defects) that is in a prepared state 10>. Here |0> and |1> denote the electron spin states mₛ = 0 and mₛ = 1. FIG. 3 is a schematic that illustrates an example of electron spin defect-based magnetometry for an AC magnetic field, in which a microwave pulse sequence is applied to an NV defect or ensemble of NV defects. The pulse sequence may also referred to as the “Hahn echo,” though other dynamical decoupling pulse sequences can be used instead. In particular, a first light pulse 302 is applied to the NV defect, or ensemble of NV defects, to place them in a prepared state |0>. While the NV defect(s) are exposed to an alternating magnetic field 300, a first π/2 microwave pulse 304 is applied to the NV defect(s) to rotate the electron spin of the NV defect(s) from the prepared state |0>to a coherent superposition |Ψ> = ⅟√2 * (|0> + e^{iφ}| 1>) which evolves over a total free precession time 2τ, if the microwave drive Rabi frequency is larger than other terms in the Hamiltonian, such as NV hyperfine coupling and the size of the magnetic field to be measured. The phase φ can be set to zero by definition, choosing the microwave drive field to be along the y axis (arbitrarily). During the free precession time, the electron spin interacts with the external magnetic field. The |1> state acquires a phase with respect to the |0>state, corresponding to a precession of the spin in the plane perpendicular to the spin quantization axis in a Bloch sphere picture. Then, a first π microwave pulse 306 is applied to “swap” the phase acquired by the |0>and |1> states. For slow components of the environmental magnetic noise, the dephasing acquired during the first half of the sequence is compensated and spin dephasing induced by random noise from the environment can be reduced. Additionally, frequency components much higher than the frequency ⅟τ average out to zero. Slow components may include, e.g., DC components and low frequency components on the order of several Hz, several tens of Hz, several hundreds of Hz, and 1-1000 kHz such as 10 Hz or less, 100 Hz or less, or 500 Hz or less, 1 kHz or less, 10 kHz or less, 100 kHz or less and 1 MHz or less. In some implementations, the pulse 306 is applied at the zero crossing of the classical AC magnetic field so that the spin phase accumulation due to the classical AC field can be enhanced. In some implementations, multiple π microwave pulses 306 are applied periodically. After applying one or more π microwave pulses 306, the phase φ and thus the magnetic field is measured by applying a second π/2 pulse 308 that projects the NV electronic spin back onto the quantization axis. The total phase accumulation is thus converted into an electron population, which can be read out optically through the spin-dependent PL of the NV defect(s). That is, a second optical pulse 310 is applied to the NV defect, or ensemble of NV defects, resulting in a photoluminescence that is read out by an optical detector. To derive the magnetic field B(t) from the PL measurement, the function describing the evolution of the S_{z} operator under the pulse sequence is multiplied by the noise and signal fields, which is then integrated to get the phase accumulation and subsequently multiplied by contrast and total photoluminescence rate to get the photoluminescence signal (sine magnetometry). For cosine magnetometry, the filter function is convolved with the power spectral density of the noise and signal fields to get the phase variance, which is then multiplied by contrast and photoluminescence rate. Sensitivity compared to the continuous-wave driving technique may improve by a factor of at least (T2/T2*)½ , in which T2 is the coherence time of the NV under AC magnetometry and T2* is inversely proportional to the NV linewidth.

An NV defect is just one example of a type of spin defect that can be used to perform electron spin defect-based magnetometry using electron spin defect bodies. In other implementations, one or more spin defects can be formed in silicon carbide. SiC defects include defects due to other substitutional atoms, such as, e.g. phosphorus, in the SiC lattice. Similar techniques for detecting magnetic fields as described herein with NV defects can be employed with the SiC defects.

According to some implementations of this disclosure, a vicinity of a roadway is provided with one or more electron spin defect-based magnetometers to detect and classify entities in and around the roadway. This detection and identification can guide subsequent operations, such as controlling roadway equipment and transmitting results of the detection and classification to one or more other systems.

In the context of traffic sensing, electron spin defect magnetometers can be used to detect a variety of “transit entities.” Transit entities include any magnetically-detectable entity traveling in or near a transportation zone. Motor vehicles such as cars and trucks, with their typically large ferromagnetic steel and iron content, have magnetic field signatures within the detectable range of electron spin defect magnetometers. For example, a car at a distance of 30 meters may cause magnetic field variations on the order of several nT, which are detectable by electron spin defect magnetometers. Bicycles, motorcycles, and powered scooters are also typically detectable in some cases, depending on their composition (e.g., size and amount of steel and iron). Pedestrians are not intrinsically detectable by magnetometry, but items carried by pedestrians, such as keys and active magnetic components (e.g., phones and other electronic devices) can themselves be detected, and the presence of a pedestrian can be inferred by location, velocity, and/or other information of the detected items. In some implementations, active electromagnetic components of vehicles can be detected, such as motors of electric cars and electric bikes. Other transit entities can also be detected, such as strollers, wheelchairs, and pets, depending on the entities’ composition and associated detectable items.

“Transit entities” need not be associated with a road, and this disclosure is not limited to detection of transit entities in car-centric environments. For example, transit entities such as drones and mass transportation systems such as trains and streetcars can also be identified and classified using spin defect magnetometry. Spin defect magnetometers can be deployed in pedestrian and bike areas, such as pedestrian plazas and trails, even when motorized vehicles may not be present.

As noted above, detection zones for inductive loop and magneto-resistive sensors are typically on the order of several feet, which dictates their sub-surface placement. Electron spin defect magnetometers do not have their placement restricted in this way but, rather, can be more conveniently located on walls, on street lamps or street lights, and in other more accessible locations.

Electron spin defect magnetometry can also, in some implementations, provide advantages over alternative measurement methods such as image analysis (e.g., based on video from vehicle-borne or fixed cameras), lidar, and radar. Unlike camera-based analysis confined to camera fields of view, spin defect-based magnetometery can offer isotropic, omni-directional sensing. Spin defect-based magnetometry can perform better than image analysis and lidar in poor weather conditions (e.g., heavy rain) that blocks visible or infrared light but may not significantly change magnetic signal responses with respect to a proper baseline. And spin defect-based magnetometry can be less susceptible than radar to incorrect or misleading measurements due to, for example, anomalous reflections.

At least two distinct detector parameters are relevant for evaluating whether information indicative of magnetic field responses will be captured. First, “sensitivity” describes the ability of a magnetometer to detect small magnetic field variations from a baseline value. Variations below a threshold sensitivity are indistinguishable from noise, while variations above the threshold sensitivity qualify as a detection. In various implementations, the electron spin defect magnetometers described herein have threshold sensitivities below 5 nT, below 2 nT, below 1 nT, or below 0.5 nT, or another value.

Second, dynamic range describes the ability of the magnetometer to measure large magnetic field variations without saturating, or, equivalently, to distinguish magnetic field variations above the threshold sensitivity. Dynamic range is typically defined with respect to the threshold sensitivity. For example, for a magnetometer with a threshold sensitivity of 5 nT and a dynamic range of 20 nT, a 2 nT variation from baseline will not be detected, while 15 nT, 25 nT, and 35 nT variations will each be detected. However, the 25 nT and 35 nT signals will both appear as maxed-out, saturated signals, and a magnitude-based analysis will be unable to distinguish between their sources (e.g., a car for the 25 nT signal and a truck for the 35 nT signal). To avoid losing information that could otherwise be used to classify transit entities, a low threshold sensitivity and a high dynamic range are preferable. Various implementations of electron spin defect magnetometers as described herein can have dynamic ranges of up to 10 nT, up to 100 nT, up to 1 µT, up to 10 µT, up to 100 µT, up to 1 mT, up to 10 mT, or up to 100 mT.

Compared to other magnetic field-based sensing method (such as inductive loop sensing as described above), electron spin defect magnetometers can offer both improved sensitivity and improved dynamic range, allowing for longer-range and more precise transit entity detection and classification.

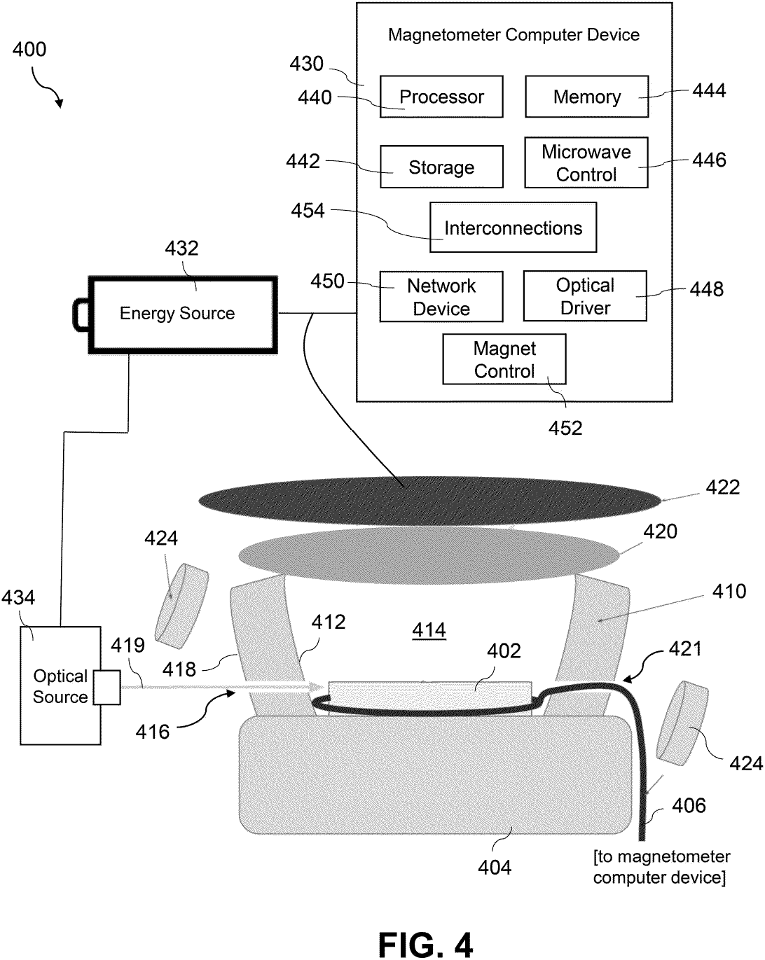

FIG. 4 shows a schematic of an example of an electron spin defect magnetometer 400, including a sensor and associated circuitry, that may be used in a traffic detecting and classification system. Other sensor configurations are within the scope of this disclosure. Examples of electron spin defect sensors, including materials, interconnections, and component layouts, are described in U.S. Application Publication Nos. 2021/0103010 and 2021/0196177, in U.S. Application Nos. 17/149,848 and 17/139,807, and in U.S. Provisional Pat. Application No. 63/076,759, each of which is hereby incorporated by reference in its entirety.

The magnetometer 400 includes an electron spin defect body 402 which is disposed on a substrate 404. The electron spin defect body 402 includes multiple lattice point defects, such as NV defects formed in diamond, as described herein. The electron spin defect body 402 containing the NV defects can be formed, in some implementations, from up to 99.999% carbon 12. In some implementations, carbon 13 is used partially in place of carbon 12. Compared to other defect materials, in some implementations diamond defect bodies provide higher dynamic ranges than other possible defect bodies.

The electron spin defect body 402 is not limited to NV defects formed in diamond, and may include other lattice point defects in other materials, such as substitutional phosphorus atoms in silicon carbide, vacancies in silicon carbide (e.g., silicon vacancies), InGaAs quantum dots, and neutrally-charged silicon vacancies (SiV⁰) in diamond. The electron spin defect body 402 can be a sub-portion of a larger body that is without electron spin defects. For example, the electron spin defect body 402 can be a top layer or top portion of a diamond body, with the rest of the diamond body (not shown) having no electron spin defects or fewer electron spin defects.

Dimensions of the electron spin defect body 402 can vary. For example, in some implementations, a thickness of the electron spin defect body 402 is less than about 1 millimeter, such as less than 750 microns, less than 500 microns, less than 250 microns, or less than 100 microns. In some implementations, the thickness is greater than about 10 microns, such as greater than 50 microns, greater than 100 microns, greater than 250 microns, greater than 500 microns, or greater than 750 microns. Other thicknesses can be used as well. Thickness of the electron spin defect body 402, as defined here, can refer to a smallest dimension of the electron spin defect body. In some cases, the thickness of the electron spin defect body 402 is defined as a distance from a surface of the electron spin defect body 402 in contact with the substrate 404 to an opposite surface of the electron spin defect body 402. In some cases, the thickness is defined as a distance from a surface of the electron spin defect body 402 delimiting the electron spin defect body 402 with respect to a larger body of which the electron spin defect body 402 is a part (as described above), to an opposite surface of the electron spin defect body 402.

Lateral dimensions of the electron spin defect body 402 (e.g., dimensions orthogonal to the thickness, such as length and width) can also vary. For example, in some implementations a width of the electron spin defect body 402 is greater than about 0.1 mm, such as greater than 0.5 mm, greater than 1 mm, greater than 2 mm, greater than 3 mm, or greater than 5 mm. In some implementations, the width is less than about 5 cm, such as less than 3 cm, less than 1 cm, or less than 5 mm. Other widths can be used as well.

In some implementations, the electron spin defect body 402 (or a larger body of which the electron spin defect body 402 is a part) is secured to the substrate 404 using an adhesive including, e.g., epoxies, elastomers, thermoplastics, emulsions, and/or thermosets, among other types of adhesives. In some implementations, the electron spin defect body 402 (or a larger body of which the electron spin defect body 402 is a part) is secured to the substrate 404 by a mechanical fixture such as a clamp, a bracket, or another fastener type.

Electrical and/or optical connections can be formed from the electron spin defect body 402, or a larger body of which the electron spin defect body 402 is a part, to electrical and/or optical elements formed on in and the substrate 404. The substrate 404 may have more than one electron spin defect body, corresponding to more than one magnetometer sensor, disposed thereon, e.g., as an array of magnetometer pixels. Electrical and/or optical elements, and interconnections therebetween, may instead or additionally be provided as discrete components that need not be integrated into the substrate 404.

The magnetometer 400 further includes a microwave field transmitter 406 that is configured to provide a microwave field to the electron spin defects of the electron spin defect body 402. In this example, the microwave field transmitter 406 includes a conductive loop formed around the electron spin defect body 402. In various implementations, the microwave field transmitter 406 may include a thin film antenna formed on a surface of the electron spin defect body 402, such as an outer-facing surface of the electron spin defect body 402, at an interface between the electron spin defect body 402 and a larger body of which the electron spin defect body 402 is a part, and/or on or in the substrate 404. The microwave field transmitter 406 may include a co-planar waveguide, a wire, a loop or a coil of electrically conductive material, such as metal.

The magnetometer 400 also includes a reflector 410, which can be mounted on the substrate 404, e.g., by an epoxy or a glue. The reflector 410 can improve a sensitivity, reliability, and/or dynamic range of magnetic field sensing, e.g., decrease a level of noise, increase a signal-to-noise ratio of the photoluminescence, or decrease a minimum detectable magnetic field strength by increasing measured photoluminescence. The reflector 410 can be oriented circumferentially around the electron spin defect body 402, e.g., surround the electron spin defect body except for openings and/or holes defined by the reflector 410. The reflector 410 includes a reflective inner surface 412 that is reflective to photoluminescence emitted by spin defects within the electron spin defect body 402. For example, the reflective inner surface 412 can be at least about 90% reflective to the photoluminescence, at least about 95% reflective to the photoluminescence, or at least about 99% reflective to the photoluminescence.

In some implementations, the inner surface 412 is reflective for wavelengths between about 620 nm and about 800 nm.

The electron spin defect body 402 is arranged inside a cavity 414 defined by the reflector 410, such that at least some photoluminescence emitted from the electron spin defects is reflected off the reflective inner surface 412 of the electron spin defect body.

In some implementations, the reflector 410 is shaped such that the reflector 410 causes collection of the emitted photoluminescence. For example, the inner surface 412 of the reflector 410 can be a rotated, truncated parabola having a focus that coincides with the electrons spin defect body 402. In some implementations, the inner surface 412 of the reflector 410 is a truncated, inverted hollow cone. Other reflector shapes are also within the scope of this disclosure, e.g., parabolas or cones including deformations from a perfect parabolic or conical shape.

In some implementations, a first base of the hollow cone or parabola (e.g., a wider of two bases of the hollow cone or parabola) has a radius of about 10 mm. In some implementations, a second base of the hollow cone or parabola (e.g., a narrower of the two bases, resting on the substrate 404) has a radius of about 1.5 mm or about 2 mm. In some implementations, the first base has a radius between 5 mm and 12 mm. In some implementations, the second base has a radius between 1 mm and 3 mm.

In some implementations, the reflective inner surface 412 is made of polished metal. In some implementations, the reflective inner surface 412 is made of a polished metal-coated plastic or ceramic.

In the example shown in FIG. 4, the reflector 410 includes a first hole 416, e.g., a hole from an outer surface 418 of the reflector 410 to the inner surface 412. Input light 419 that excites the spin defects of the electron spin defect body 402 can be directed from outside the cavity 414 through the first hole 416 to illuminate the electron spin defect body 402. In this example, the reflector 410 also includes a second hole 421 through which the microwave field transmitter 406 passes. However, in some implementations input light and/or a microwave field transmitter are provided in ways besides holes in a reflector, e.g., at different positions from the positions shown in FIG. 4. Moreover, some implementations of the magnetometer do not include a reflector.

The example magnetometer 400 includes an optical filter 420. The optical filter 420 is configured to pass photoluminescence emitted by the electron spin defects while blocking another wavelength. For example, the electron spin defects can be excited by input light of a first wavelength, the photoluminescence can be substantially of a second wavelength, and the optical filter 420 can be configured to pass the second wavelength and block the first wavelength. Blocking the input light can be desirable, because otherwise some of the input light can be collected and contribute to measured photoluminescence magnitude, even though the input light is not photoluminescence. This can reduce a sensitivity of magnetic field collection (e.g., by introducing noise), or may lead to incorrect sensing determinations.

Various types of filters can be included. For example, the optical filter 420 can be a bandpass filter where the second wavelength is in the passband and the first wavelength is outside the passband, or the optical filter 420 can be a high-pass filter where the second wavelength is greater than the cutoff wavelength and the first wavelength is less than the cutoff wavelength. In some implementations, optical filtering is instead or additionally performed at the photodetector 422.

The photodetector 422 is arranged to detect photoluminescence received from the electron spin defect body 402. As described herein, the detected photoluminescence (e.g., a magnitude of the photoluminescence) is indicative of a magnetic field (e.g., a time-varying magnetic field) to which the electron spin defect body 402 is exposed.

The example magnetometer 400 also includes a magnet 424. The magnet 424 can be arranged adjacent to the electron spin defect body 402. The magnet 424 is provided to induce the Zeeman effect and lift the degeneracy of the mₛ = +/- 1 spin sublevels. In some implementations, the magnet 424 is a permanent magnet. In some implementations, the magnet 424 is an electromagnet. The magnet 424 can be positioned directly on the substrate 404, on the electron spin defect body 402, and/or in another location. The magnet geometry can be chosen to minimize effects of inhomogeneous broadening between distinct defects in the electron spin defect body 402.

In some implementations (e.g., some scalar magnetometry implementations), the magnet 424 is arranged such that the bias magnetic field generated by the magnet 428 aligns with spin axes of the NV defects, e.g., projects equally onto multiple axes of the four possible orientation axes of the NV defects. For example, in a sample in which spin axes point along 0°-180° and 90°-270°, the magnet 424 might be arranged to apply a magnetic field in the 45°-225° direction, such that applied magnetic field strengths along the spin axes are equal and magnetic field strength along both axes is measured together.

In some implementations (e.g., some multi-vector magnetometry implementations), the magnet 424 is arranged so as to split PL intensity lines from the NV defects into four individual lines, representing the four possible orientation axes, by causing each spin axis to be exposed to a different magnetic field. For example, in the example given above, the magnet 424 (in some implementations, more than one magnet) would be arranged to apply different magnetic field strengths in the 0°-180° direction and the 90°-270° direction, such that magnetic field strengths along the axes can be measured independently. Note that some implementations of magnetometers do not include a magnet.

Although the example magnetometer 400 is shown as including free-space light transmission, in some implementations input light, output photoluminescence, or both are carried at least partly by optical fibers.

The magnetometer 400 also includes a magnetometer computer device 430, one or more energy sources 432, and an optical source 434, any one or more of which can be coupled by wired and/or wireless connections. The one or more energy sources 432 can include one or more energy storage devices (e.g., rechargeable and/or non-rechargeable batteries), grid connections (e.g., to a municipal energy grid), and/or energy generating devices (e.g., a mounted solar panel). The magnetometer 400 can be relatively low-power such that batteries can last for years without needing to be replaced or recharged. However, grid connections and energy generating devices can provide resiliency and obviate the need for periodic battery replacement.

The optical source 434 is configured to emit input light to the electron spin defect body 402. The input light emitted by the optical source 434 can include a first wavelength that excites the one or more lattice point defects within the electron spin defect body 402 from a ground state to an excited state. The first wavelength is different from a second wavelength that is emitted by the lattice point defects upon relaxation. The first wavelength can be, e.g., about 532 nm to excite NV defects in the electron spin defect bodies. The optical source 434 can include, e.g., a light emitting diode (LED), a laser, or a broadband source that includes filters configured to block transmission of wavelengths other than those of the first wavelength used to excite the lattice point defects.

LEDs as the optical source 434 can be particularly useful in the context of traffic-sensing magnetometers. First, LEDs tend to consume less power than equivalent lasers, allowing the magnetometers to remain in position by a roadway for a longer period of time without needing replacement, recharging, or battery replacement, in contrast to, e.g., medical magnetometers for which recharging is convenient. Second, it is expected that traffic-sensing magnetometers will be handled by people in an uncontrolled manner, such as due to vandalism, breaking/malfunction, in the aftermath of vehicle crashes that may dislodge the magnetometers, etc. In such circumstances, lasers might be dangerous, while LEDs provide a lower density of optical power and are less likely to cause injury.

The magnetometer computer device 430 is integrated together with other components of the magnetometer 400, e.g., mounted in an enclosure together with sensing components of the magnetometer 400 or otherwise closely coupled to the sensing components of the magnetometer 400, and includes multiple modules/devices that together control operation of the magnetometer 400. Interconnections 454 (e.g., wired and/or wireless connections such as cables and Bluetooth connections) couple together components of the magnetometer 400.

In the example of FIG. 4, one or more processors 440 are configured to perform computing and control operations of the magnetometer 400 in conjunction with other modules/devices (which can be hardware and/or software modules/devices) of the magnetometer computer device 430. For example, one or more computer-readable storage devices 442 and/or computer-readable memory devices 444 store non-transitory, computer-readable instructions that can be executed by the one or more processors 440 to perform computing and control operations. In many implementations, measurement results (e.g., photoluminescence magnitudes) are transmitted from the magnetometer 400 for processing and analysis on another computing device. However, in some implementations, any one or more of the analysis methods described in this disclosure can be performed locally at the magnetometer computer device 430 itself. For example, if the magnetometer 400 is configured in a simple entity-counting mode, then simple on-board electronics can be used for analysis. The magnetometer computer device 430 can also perform periodic or triggered self-calibration operations, as described in further detail below.

A microwave field control driver 446 is coupled, e.g., electrically connected, to the microwave field transmitter 406. The microwave field control driver 446 is configured to provide a microwave source signal (e.g., as a voltage and/or a current) to the microwave field transmitter 406 so that the microwave field transmitter 406 emits microwave fields toward the electron spin defect body 402. For example, the microwave field control driver 446 can be implemented as analog and/or digital circuitry configured to output, as the microwave source signal, a voltage and/or current signal having a frequency matching a target microwave field frequency to be emitted by the microwave field transmitter 406. The microwave source signal can optionally be a pulsed microwave source signal. In some implementations, a microwave frequency of the microwave source signal is between about 2 GHz and about 4 GHz. In some implementations, the microwave field transmitter 406 (powered and/or controlled by the microwave field control driver 446) emits signals at multiple frequencies spaced apart from one another to drive additional energy level splittings. For example, in some implementations, the microwave field transmitter 406 is operated to emit microwave signals that address NV hyperfine transitions. In some implementations, the microwave field control driver 446 is configured to provide a control signal that generates a pulsed microwave signal at the microwave field transmitter 406. In some implementations, the microwave field control driver 446 is configured to provide a control signal that generates a continuous wave microwave signal at the microwave field transmitter 406.

An optical driver 448 is coupled, e.g., electrically connected, to the optical source 434 and controls operations of the optical source 434, e.g., by provision of appropriate electrical signals. For example, the optical driver 448 can be implemented as analog and/or digital circuitry configured to turn the optical source 434 on and off by applying currents and/or voltages to the optical source 434. For example, when the optical source 434 includes one or more light-emitting diodes, the optical driver 448 can be configured to apply voltages to each of the one or more light-emitting diodes, the voltages higher than turn-on voltages of the one or more light-emitting diodes. When the optical source 434 includes one or more lasers, the optical driver 448 can be configured to apply a current to each of the one or more lasers, the current greater than or equal to threshold currents of the one or more lasers.

A network device 450 is configured to communicate wirelessly (e.g., by Bluetooth, Wi-Fi, cellular signals, and/or other wireless transmission types) and/or over wired connections (e.g., cabled connections) with one or more devices external to the magnetometer 400. For example, in some implementations the network device 450 includes one or more transceivers. In some implementations, the network device 450 includes one or more antennas, such as Bluetooth, Wi-Fi, and/or cellular antennas. The one or more other devices can include other magnetometers in a vicinity of the magnetometer 400, a local computer system (e.g., local computer system 512), a remote computer system (e.g., remote computer system 514), or a combination thereof. For example, photoluminescence data received from the photodetector 422 can be forwarded to the local traffic analysis system and/or the remote computer system for analysis.

A magnet control driver 452 is configured to control the magnet 424, e.g., by applying currents to the magnet 424 to generate magnetic fields, when the magnet 424 is an electromagnet. For example, the magnet control driver 452 can be implemented as analog and/or digital circuitry configured to apply currents to the magnet 424, the currents having time-varying characteristics that match target time-varying characteristics of the magnetic fields to be applied, e.g., in order to lift degeneracies of spin sublevels. For example, to apply a constant magnetic field, the magnet control driver 452 is configured to apply a constant current to the magnet 424. In some implementations, a higher current applied by the magnet control driver 452 corresponds to a higher magnetic field magnitude generated by the magnet 424, and the magnet control driver 452 is configured to apply a current that causes generation of a magnetic field with a target strength.

Other modules/devices may instead or additionally be included in the magnetometer computer device 430. More details on implementations of computing systems within the context of this disclosure, including the magnetometer computer device 430, the local computer system 512, and the remote computer system 514 are provided below.

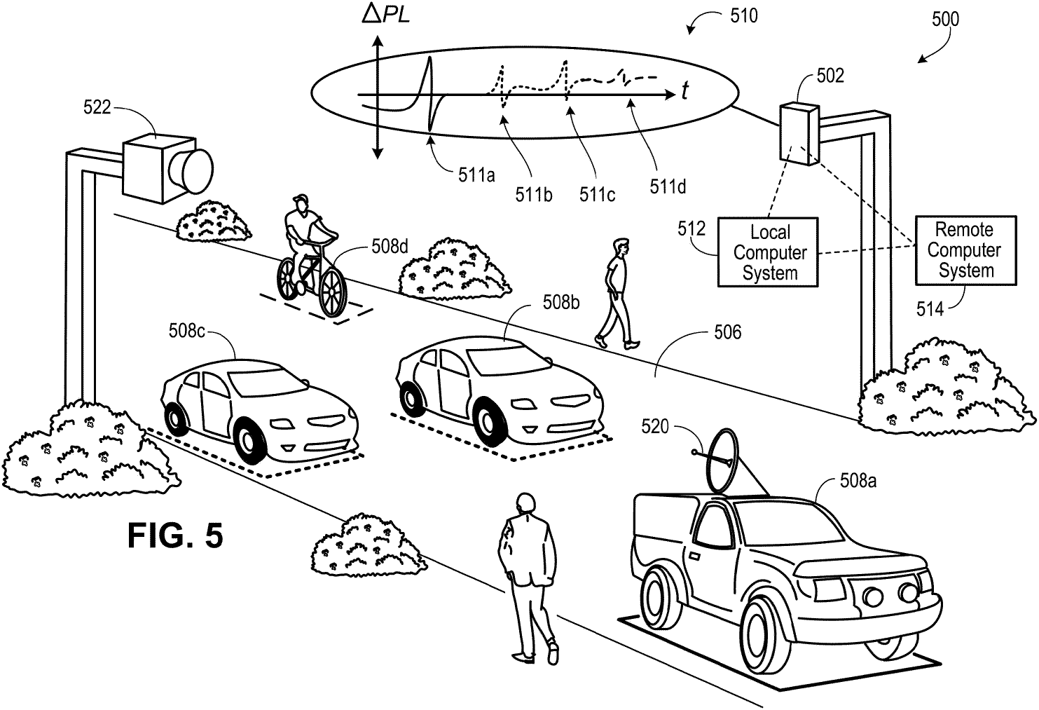

FIG. 5 shows an example of an electron spin defect magnetometer 502 in a sensing environment 500. The magnetometer 502 is fixed on a mount 504 in a vicinity of a road 506. Mounts for magnetometers can vary in various implementations, and can include any one or more of signal poles, signage posts, street light posts, pre-existing walls and barriers (e.g., tunnel walls or highway barriers), or mounts specifically placed to receive the magnetometers. In some implementations, the mounts include electrical hookups (e.g., grid connections and/or solar panels in combination with batteries) to power mounted magnetometers.

The magnetometer 502 detects magnetic field variations caused by transit entities traveling in or located in a vicinity of the road 506. Specifically, the magnetic field variations cause a time-domain change in photoluminescence ΔPL detected at a photodetector of the magnetometer 502, in which the time-domain change in photoluminescence is proportional to the magnetic field variations. In this example, four transit entities 508a, 508b, 508c, and 508d are present in the road 506. Transit entity 508a is a truck, transit entities 508b, 508c are cars, and transit entity 508d is a bicycle. The succession of these transit entities 508 passing the magnetometer 502 leads to a ΔPL signal 510 as a function of time t. For purposes of illustration, the signal 510 is shown as a sequence of four separate magnetic field signatures 511a, 511b, 511c, 511d corresponding, respectively, to the four transit entities 508a, 508b, 508c, 508d. For example, if the four transit entities 508 are spaced sufficiently far apart from another, their magnetic field contributions will be detected one at a time as separate magnetic field signatures. Or, if the magnetometer is configured for an anisotropic detection direction as described in further detail below, each transit entity 508 will contribute a separate magnetic field signature as each transit entity 508 passes by the magnetometer 502 at a different time. As shown in FIG. 5, solid, dotted, or dashed box outlines underneath each transit entity 508a, 508b, 508c, 508d correspond to matching line types of portions of the signal 510 corresponding to each transit entity 508a, 508b, 508c, 508d. For example, a solid box outline underneath transit entity 508a indicates that solid-line magnetic field signature 511a is induced by transit entity 508a.

In practice, unless the magnetometer 502 is configured for an anisotropic detection direction or unless the transit entities 508 are spaced far apart from one another, the ΔPL signal may not include signal contributions from multiple transit entities one at a time in an isolated fashion. Rather, at any given time, the total ΔPL signal at the magnetometer 502 can be a result of magnetic field variations caused by multiple transit entities 508 (e.g., a sum of the magnetic field variations). The magnitude of magnetic field variations from any one transit entity 508 can be a combination (e.g., a convolution) of a distance of the transit entity 508 from the magnetometer 502 and an intrinsic magnetic response strength of the transit entity 508 (e.g., based on a size of the transit entity 508, an amount of ferromagnetic material present in the transit entity 508, a presence of active magnetic devices in the transit entity 508, etc.) such that, in some cases, a small-but-close transit entity 508 will cause a smaller ΔPL than a larger-but-far transit entity 508, the two ΔPLs being sensed simultaneously as a ΔPL_{total.} Given known physical characteristics of the magnetometer 502, a ΔPL vs. t signal can be converted into a ΔB vs t signal that represents actual changes in the magnetic field at the magnetometer 502.

Various techniques can be used to decompose an aggregate magnetic field signal into constituent signals from separate transit entities. In some implementations, the aggregate magnetic field signal is filtered, e.g., to remove frequency components that are less likely to correspond to transit entities. In some implementation, one or more of model fitting (e.g., based on a parameter-dependent model waveform caused by a transit entity), principal component analysis, or autocorrelation analysis (e.g., for signals from two magnetometers or signals detected by one magnetometer at different times) can be used to decompose the aggregate magnetic field signal. When multiple sensors are used, triangulation and related methods can be used to correlate signal components from different sensors and, accordingly, to decompose aggregate magnetic field signals based on the correlations.

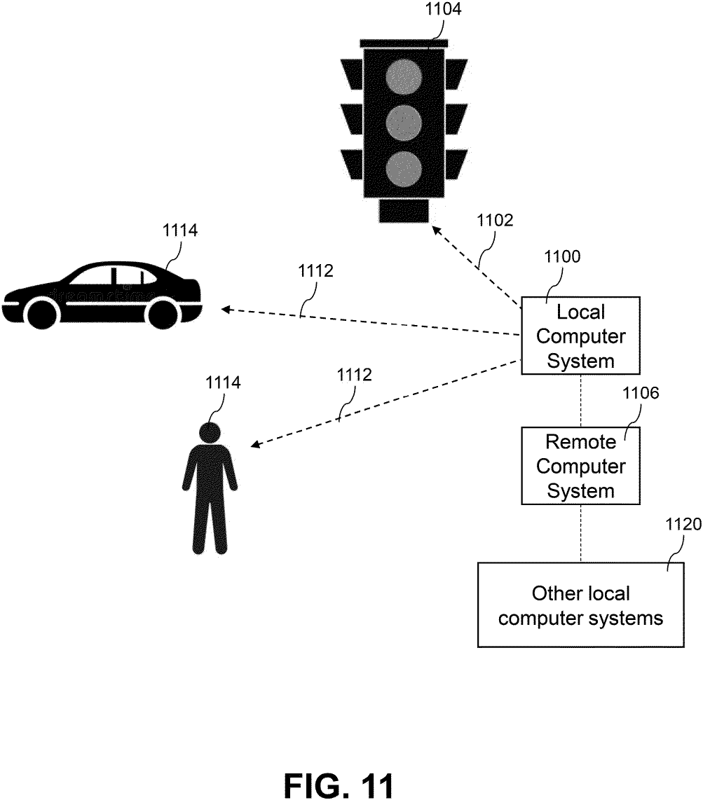

Besides the magnetometer 502, in some implementations a local computer system 512 is also located in the vicinity of the road 506, and a remote computer system 514 is located at one or more remote locations (e.g., as a cloud-based system). The local computer system 512 and the remote computer system 514 can include computer components such as processing devices, memory/storage devices, and network transmission systems as described for the magnetometer computer device 430 and as described in additional detail below in reference to FIG. 11. The local computer system 512 can be powered as described for the magnetometer 400, e.g., using one or more of batteries, grid connections, or power generating devices. In some implementations, the local computer system 512 is built into an infrastructure component as described for the magnetometer 502, e.g., included in signal poles, signage posts, street light posts, pre-existing walls and barriers (e.g., tunnel walls or highway barriers), or mounts specifically placed to receive the local computer system 512.

The local computer system 512 is configured to receive magnetic field measurements and/or other data from the magnetometer 502 and process the data to identify and classify transit entities. In some implementations, the magnetometer 502 itself has relatively few computer resources and may, for example, simply obtain sensor data and transmit the sensor data to the local computer system 512. In some implementations, the magnetometer 502 performs at least some processing (e.g., preliminary filtering steps and/or counting steps) but also sends data to the local computer system 512 for more substantive analysis, e.g., analyses as described below. However, as noted above, any of the analyses described here can, in some implementations, be additionally or alternatively performed by the magnetometer 502 itself, e.g., by the magnetometer computer device 430. Moreover, in some implementations, the local computer system 512 is absent, in which case the magnetometer may transmit data directly to the remote computer system 514 for performance of any or all of the analyses described herein.

In some implementations, the magnetometers 502 are configured only for short-range communication, e.g., using Bluetooth or another local communication. In these and some other implementations, the local computer system 512 acts as an intermediate signal-forwarding system between the magnetometers 502 and the remote computer system 514. For example, data from the magnetometers 502 can be first sent to the local computer system 512 and transmitted from there (e.g., over an Internet connection via a wireless network) to the remote computer system 514 for processing, in addition to any processing that may be performed by the local computer system 512. Likewise, commands and software updates from the remote computer system 514 can be received at the local computer system 512 and passed from there to the magnetometers 502.

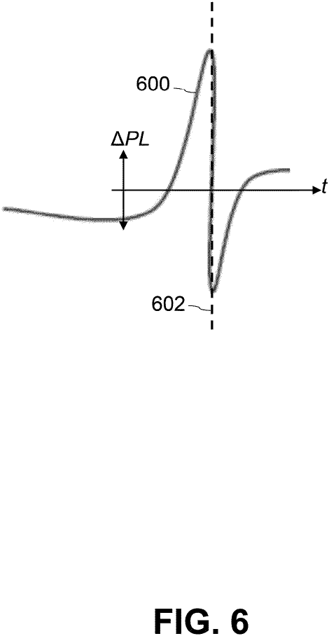

FIG. 6 shows an example magnetic field signature 600 caused by a transit entity. In general, the shape and magnitude of a given magnetic field signature depends on, among other factors, a type of the magnetic field entity (e.g., an active magnetic field emitter compared to a passive ferromagnetic entity), a size/mass of the magnetic field entity, a velocity of the magnetic field entity, and a distance between the magnetic field entity and a detecting magnetometer. The example magnetic field signature 600 reflects detection of an active magnetic field emitter, characterized by the signature 600 flipping sign at a time 602 at which the transit entity having the active magnetic field emitter passes by the detecting magnetometer (switches from approaching the detecting magnetometer to moving away from the detecting magnetometer). By contrast, in some cases a signal from a passive, ferromagnetic transit entity is single-peaked without a sign switch. The velocity (e.g., speed) of the transit entity can determine a shape of the magnetic field signature (e.g., a frequency band of the magnetic field signature): for example, a faster transit entity can correspond to a narrower magnetic field signature, and a stationary transit entity can correspond to a magnetic field signature that is a DC offset. For a given transit entity, a magnitude of the transit entity’s magnetic field signature is larger when the transit entity is closer to the detecting magnetometer.

The magnetic field signature 600 can be analyzed in one or more of a variety of ways to classify the transit entity that caused the magnetic field signature. For example, in some implementations one or more predetermined algorithmic methods are used to performed classification, such as filtering, model fitting, principal component analysis, autocorrelation analysis, and/or triangulation/multilateration can be performed to decompose a detected magnetic field signal into component signatures and perform classification on the component signatures. For example, a signature can be fit to a model, and best-fit parameters of the fitting can indicate a type of transit entity that generated the signature. The signature can be compared to multiple stored template signatures to determine a type of entity corresponding to the signature. For example, for each stored template signature, a distance metric (e.g., a cross-correlation) can be computed, and a template signature corresponding to the smallest distance metric is determined to be a match for the transit entity type of the signature.

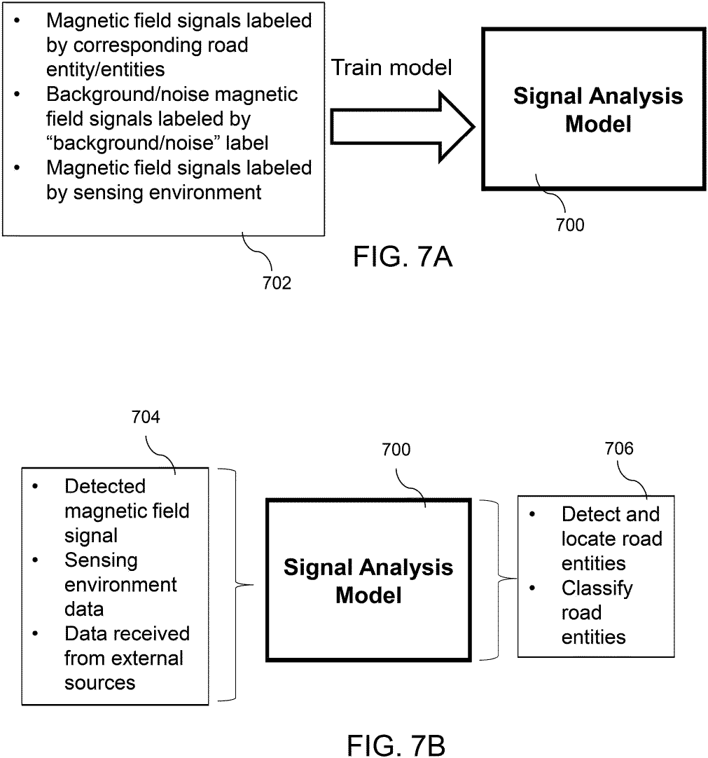

In some implementations, one or more magnetic field signatures (e.g., an aggregate signal detected at an electron spin defect magnetometer) are analyzed using a trained machine learning model, such as a neural network. The analysis can be performed on the raw signal(s) themselves or on signal(s) that have been preprocessed, e.g., using filtering, model fitting, principal component analysis decomposition, autocorrelation analysis, and/or other methods. As illustrated in FIG. 7A, a signal analysis model 700 is trained using training data 702. The signal analysis model 700 can be, for example, a neural network in which connected nodes, aggregated into multiple layers, perform successive transformations of input data. In some implementations, training of the signal analysis model 700 is performed locally, e.g., at the local computer system 512, in some cases using locally-obtained data to customize the signal analysis model 700 for a specific area of road. In some implementations, training of the signal analysis model 700 is performed remotely, e.g., at the remote computer system 514, and the trained model is loaded onto the local computer system 512 for local processing and/or stored at the remote computer system 514 for remote processing.

The training data 702 includes various types of labeled data. For example, in some implementations, the training data 702 includes one or more of: individual magnetic field signatures labeled by their corresponding generating transit entities and parameters thereof, combinations of magnetic field signatures labeled by their corresponding combined generating transit entities and parameters thereof, background and noise magnetic field signals labeled with a “background/noise” label, magnetic field signals, of various types, labeled by their corresponding sensing environments, or other types of training data.

Based on the labeled magnetic field signatures and combinations of them, the signal analysis model 700 is trained to (i) decompose detected magnetic field signals into constituent signatures (e.g., extract the signals) and (ii) classify the constituent signatures to determine their corresponding transit entity sources. An example of a labeled magnetic field signature is a ΔPL vs. t or ΔB vs t magnetic field signal labeled with parameters (e.g., as a feature vector) {type = sport utility vehicle, weight = 2200 kg, length = 500 cm, height = 190 cm, primary signal source = steel, trajectory}. The “trajectory” data element represents trajectory information of the sampled transit entity with respect to the magnetometer(s) used to obtain the sample magnetic field signal. For example, the trajectory data element may include a time series of coordinates of the transit entity with respect to the magnetometer(s), velocity data of the transit entity, position of the sampling magnetometer(s) (e.g., buried or elevated), and/or other positional data. For a combined signal caused by multiple transit entities, a labeling set of parameters are provided for each of the multiple transit entities. In some implementations that incorporate multi-vector magnetometry as described above, magnetic field signals (e.g., labeled signals used for training and/or signals input into trained models for operational classification) are provided as multiple component signals corresponding to different sensing directions.

Based on the background and noise magnetic field signals provided in the training data 702, the signal analysis model 700 learns to identify background and noise components of sensed magnetic field signals, whether those components are sensed alone or in combination with actual transit entities to be detected and classified. For example, magnetic field signals corresponding to Earth’s magnetic field, power lines (e.g., at 50/60 Hz), radio and other wireless transmissions that do not originate with local transit entities, solar flares, the aurora borealis, high-power equipment construction equipment, drones that are not to be identified as transit entities and/or other background and noise sources can be provided to the signal analysis model for training. As a result, the signal analysis model 700 is trained to remove background and noise components from sensed magnetic field signals, such as by, for example, applying a frequency filter to the sensed magnetic field signals to filter out frequencies known to correspond to background and noise sources. In some implementations, background and noise signals are additionally or alternatively filtered out before processing by the signal analysis model 700, e.g., in an algorithmic fashion based on known background and noise sources (such as 50/60 Hz power lines) and/or based on in-situ magnetometer calibration, as described in more detail below.

Based on magnetic field signals of various types labeled with their corresponding sensing environments and, in some implementations, other parameters such as the parameters listed above in reference to the labeled magnetic field signatures, the signal analysis model 700 learns to account for environmental conditions when detecting and classifying transit entities. Sensing environment can include any one or more of time/date characteristics (e.g., time of day, day of the week, season, holiday or non-holiday status), weather characteristics (e.g., temperature, precipitation type), setting (e.g., urban or rural, country), and/or other data types.

As shown in FIG. 7B, in use, the trained signal analysis model 700 is provided with input data 704 from an electron spin defect magnetometer and, in some implementations, from one or more additional sources as well. The input data 704 includes magnetic field signals from the magnetometer (in either or both of ΔPL vs. t or ΔB vs t form). In some implementations, the input data 704 includes current environmental data and/or other data types. The current environmental data, such as temperature data and precipitation data, can be detected locally at the roadway itself using local sensors (e.g., sensors integrated into a local magnetometer or local computer system) and/or can be provided from a remote source and received at the analyzing computer system (e.g., from a government or commercial weather tracking entity).

In some implementations, the input data 704 can instead or additionally include other types of data received from external sources. An important class of such data is input traffic data from transit entities and/or from non-magnetometer traffic sensors. As shown in FIG. 5, some transit entities (e.g., transit entity 508a) can be equipped with measurement devices 520 such as radars or cameras. In addition, or alternatively, there can be fixed measurement devices 522 present besides spin defect magnetometers, such as fixed traffic cameras. Data collected by the vehicle-borne measurement devices 520 and the fixed measurement devices 522 can include, for example, data representing transit entity positions and velocities. This data is transmitted between vehicles as vehicle-to-vehicle messages (V2V), between vehicles and infrastructure as vehicle-to-infrastructure (V2I) messages, and between infrastructure components as infrastructure-to-infrastructure (I2I) messages. Besides any fixed non-magnetometer measurement devices 522, “infrastructure” also includes the local computer system 512 and the remote computer system 514. In this context, electron spin defect magnetometers can be envisioned as a portion of a larger traffic-sensing system that can also rely on these other types of input data, whose collection and analysis have been described elsewhere.

Data from V2I and I2I messages can be used to complement magnetometry data. For example, as part of the analysis process, the data from these other sources can be cross-referenced with magnetometry data to more accurately locate and/or classify transit entities. The data from the other sources can also fill gaps in the magnetometry analysis, e.g., to reveal the presence of entities (such as pedestrians without phones or other detectable items) that are not detected by magnetometry.

Referring again to FIG. 7, based on the input data 704, the signal analysis model 700 produces output data 706. The output data 706 includes locations of detected transit entities and classifications of those transit entities.

The locations of the transit entities can be determined in the context of various coordinate systems. In some implementations, the locations are determined in a global coordinate system such as GPS. In some implementations, the locations are determined in a local coordinate system that is specific to a particular portion of road, a particular intersection, or another location. In some implementations, the locations are first determined in the local system and are then mapped to the global coordinate system.

Classification of the transit entities can include determination of any or all of the parameters described in reference to training the signal analysis model 700, or other parameters. Entity types include at least pedestrians, bicycles, motorcycles, accessory devices (e.g., wheelchairs and strollers), trains, and cars and trucks of various types, such as sedans, sport utility vehicles, and semi-trailer trucks. Weight, length, height, and width describe physical parameters of the transit entity. Weight, while not able to be sensed directly, can in some cases be estimated based on signal strength, for example, in combination with measured dimensions and known densities of identified materials. Primary signal source refers to a physical originating source of the detected signal, such as a steel body (e.g., for a vehicle) or a cellular phone transmission (for a pedestrian). Trajectory refers to a trajectory of the transit entity, including, for example, a time series of coordinates of the transit entity, velocity data of the transit entity, and/or other positional data.

Other forms and implementations of the signal analysis model 700 are also within the scope of this disclosure. For example, in some implementations the signal analysis model includes multiple sub-models that have been trained singly or jointly. For example, input data first can be fed into a noise-removal sub-model that removes background and noise signals from the input data. Cleaned data output by the noise-removal sub-model then is provided to an entity detection and classification sub-model that provides output data such as output data 706.

Signal analysis can include various operations. For example, in an anomaly detection process, anomalous data (e.g., signals having a magnitude larger than a threshold, or signals having shapes or frequency characteristics that do not meet one or more conditions) can be identified and removed. As another example, in a peak identification process, peaks are identified, e.g., using wavelet transformation or another method. These and other operations can be performed algorithmically, using a machine learning model trained to perform the operations, or both algorithmically and using a machine learning model, in various implementations.

In some implementations, as noted above, magnetometers are configured so as to measure magnetic field signals along multiple axes. The multi-axis signals can be used as input data for algorithmic and/or machine learning-based analysis. Because these signals essentially contain additional location data compared to aggregate intensity signals without directional decomposition, in some implementations transit entities can be located and classified more accurately and/or with data from fewer magnetometers.

Some implementations according to this disclosure include multiple spin defect magnetometers. The relatively low cost of the spin defect magnetometers allows them to be used in groups of two or more, including groups of dozens or even hundreds of magnetometers in a vicinity of a transportation area. In large scale implementations, many thousands of magnetometers can be distributed throughout a transportation network to collectively identify and classify transit entities in the transportation network over wide distances.

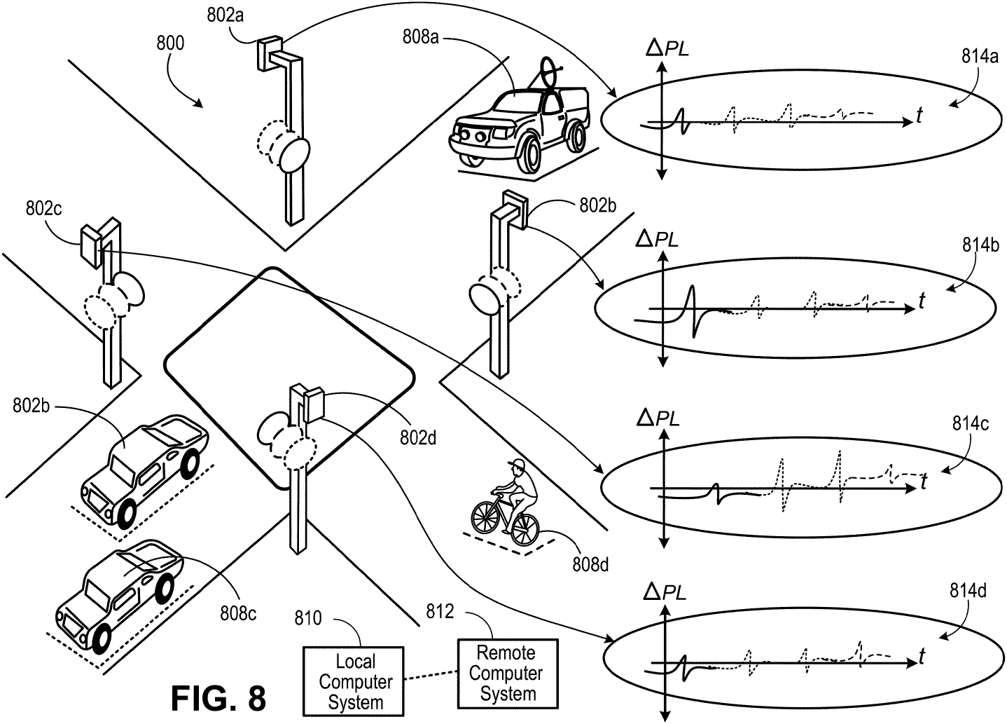

As shown in FIG. 8, in an example of distributed, multi-magnetometer sensing, four spin defect magnetometers 802a, 802b, 802c, 802d are located on respective signal poles in a vicinity of a four-way intersection 800. Four transit entities 808a, 808b, 808c, 808d (a truck, a car, a car, and a bicycle, respectively) are present in or around the intersection 800 and cause magnetic field variations to be sensed by the four magnetometers 802. A local computer system 810 is also present at the intersection 800 and is configured to communicate with (e.g., transmit data back and forth with) the magnetometers 802 and, in some implementations, a remote computer system 812.

The four spin defect magnetometers 802a, 802b, 802c, 802d generate respective magnetic field signals 814a, 814b, 814c, 814d. Because the magnetometers 802 are in different locations, the magnetic field signals 814 are different from one another, reflecting the different influences of each transit entity 808 on each magnetometer 802 at each moment in time. In some implementations, the signals 814 are analyzed individually by the magnetometers 802, the local computer system 810, and/or the remote computer system 812. However, by analyzing the signals 814 in a combined analysis, richer entity detections and classifications can be performed. Such a combined analysis can be performed, for example, by the local computer system 810 and/or by the remote computer system 812.

As in FIG. 5, solid, dotted, or dashed box outlines underneath each transit entity 808a, 808b, 808c, 808d correspond to matching line types of portions of the signals 814 corresponding to each transit entity 808a, 808b, 808c, 808d. For example, a solid box outline underneath transit entity 808a indicates that solid-line magnetic field signatures in each signal 814 correspond to transit entity 808a.

For a combined analysis, the analyzing computer system receives the multiple magnetic field signals 814. In some implementations, one or more preprocessing steps are performed to normalize or regularize the magnetic field signals 814. For example, one or more of the signals 814 can be time-shifted to put the signals 814 on a uniform time axis (e.g., to account for transmission and other delays). Magnitude scaling can be performed to account for stronger or weaker fluorescence responses in some magnetometers 802 compared to other magnetometers 802. Filtering and/or other signal processing can be performed to remove background and noise signal contributions and/or to at least partially decompose the signals 814 into constituent signatures generated by different transit entities 808.

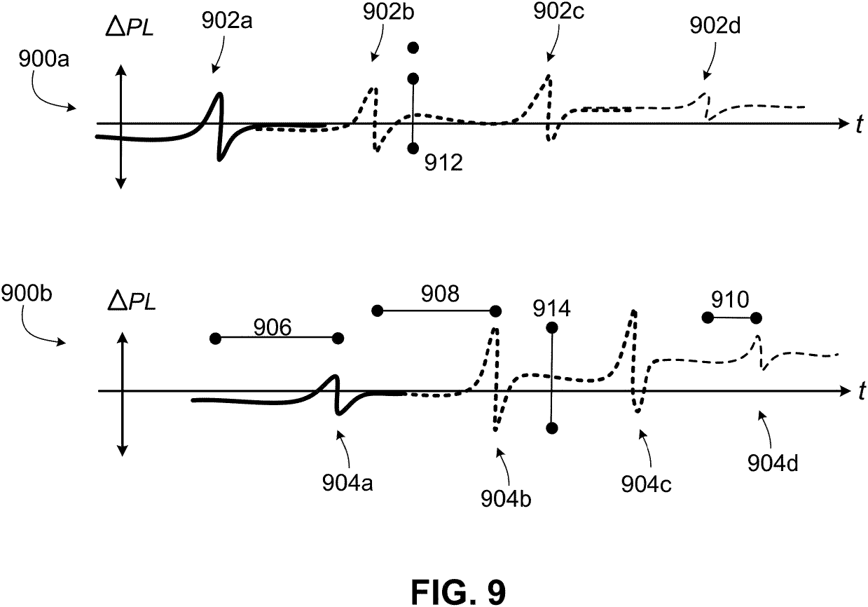

The (possibly modified) magnetic field signals 814 are, in some implementations, analyzed by pre-defined algorithmic means. For example, based on known locations of each magnetometer 802, a multilateration process (e.g., triangulation based on signal strengths and detection times) can be performed to determine transit entity locations. The multilateration process depends on timings and magnitudes of magnetic field signatures corresponding to a same transit entity as received at different magnetometers. For example, as shown in FIG. 9, a first magnetic field signal 900a is obtained from a first magnetometer and a second magnetic field signal 900b is obtained from a second magnetometer. Each signal 900a, 900b includes, in sequence, four signatures 902a, 902b, 902c, 902d and 904a, 904b, 904c, 904d corresponding to four different transit entities. However, when compared on the same time axis, the signatures are time-shifted with respect to one another. For example, a time gap 906 exists between corresponding signatures 902a and 904a, a time gap 908 exists between corresponding signatures 902b and 904b, and a time gap 910 exists between corresponding signatures 902d and 904d (e.g., between peaks of the respective pairs of signatures), where lengths of the time gaps 906, 908, 910 need not be equal but, rather, depend on the particular trajectories of each transit entity and the respective locations of the magnetometers. Signature curve shapes can also be compared. For example, signature 902b has a peak magnitude 912 that is less than a peak magnitude 914 of signature 904b, which can, in some implementations, correspond to a closer approach of the corresponding transit entity to the second magnetometer than to the first magnetometer. In some cases, different magnitudes can be used to determine/estimate different transit entity-to-magnetometer distances, e.g., based on field strength falling off with distance as proportional to ⅟r³, where r is the distance. These and other characteristics of the data can be used to determine location and other information of the transit entities.

Instead of, or in addition to, algorithmic analysis, the (possibly modified) signals 814 are provided to a trained machine learning signal analysis model. The signal analysis can have any or all of the characteristics described with respect to the signal analysis model 700, including methods of training and types of input and output data. In the case of multiple magnetometers, the machine learning model is also trained using labeled training data from multiple magnetometers. The training data represents signals from single or combined transit entities as detected by multiple magnetometers (in multiple locations) at the same time. For example, the model is trained on multiple signals corresponding to the label {type = sport utility vehicle, weight = 2200 kg, length = 500 cm, height = 190 cm, primary signal source = steel, trajectory}, each of the multiple signals captured by a different magnetometer in the vicinity of the sport utility vehicle. The “trajectory” data element includes relative location information that represents the trajectory of the sport utility vehicle with respect to the different magnetometers. This can include relative trajectories (e.g., with each magnetometer having coordinates (0,0)) and/or absolute trajectories (e.g., the trajectory in absolute coordinates, the same for each magnetometer) along with a coordinate, in the same coordinate system, of the generating magnetometer.

Based on this training, the signal analysis model learns to correlate signals from multiple magnetometers to one another in order to provide, as output data based on input magnetic signal data from multiple magnetometers, data identifying and classifying transit entities that contributed to the input magnetic signal data. The output data can include locations, trajectories, and transit entity parameters, as described above in reference to FIG. 7.

To provide for more stable magnetic measurements over time, in some implementations an electron spin defect magnetometer is configured to perform periodic self-calibrations. One class of self- calibration allows the magnetometer to adjust to changing levels of background/noise over time. For example, the construction of new power lines or new buildings may increase an average level of background magnetic noise compared to when the magnetometer was initially installed. To account for this, in some implementations the magnetometer periodically obtains a sample magnetic field signal. The sample magnetic field signal can be processed to remove contributions of transit entities (e.g., by a frequency-filtering process), and/or the sample magnetic field signal can be substantially composed of background/noise signals as-detected. The sample magnetic field signal is used to set a new background baseline, e.g., by passing the sample magnetic field signal into a trained background determination machine learning model. The newly-determined background baseline is then used to process future signals collected by the magnetometer. For example, the newly-determined baseline can be used during an algorithmic pre-processing step, and/or the newly-determined baseline can be used to modify (e.g., partially re-train) a signal analysis machine learning model.

In a second class of self-calibration, a test magnetic field signal is detected and used to calibrate future measurements. For example, in some implementations a magnetometer includes a small electromagnet that can be activated to produce a test magnetic field having known characteristics, such as magnitude and timing. The magnetometer detects this known test magnetic field and produces a test magnetic field signal (e.g., a photoluminescence signal). Deviations between the test magnetic field PL signal and an expected magnetic field PL signal are indicative of magnetometer-specific sensing characteristics that can be accounted for during future analysis. For example, if a magnetometer has a weakening light source, photoluminescence signals from the magnetometer may be smaller than expected. An appropriate scaling constant to account for this difference is determined using self-calibration, and future photoluminescence signals can be scaled by the scaling constant during future magnetic signal processing.

Operations associated with self-calibration, like other operations described throughout this disclosure, can be performed on a magnetometer computer system, on a local computer system, on a remote computer system, or jointly between combinations of these systems. Self-calibration can be performed at fixed intervals (e.g., weekly or monthly) and/or in response to an explicit self-calibration command, such as a command sent from a remote computer system to a local computer system.

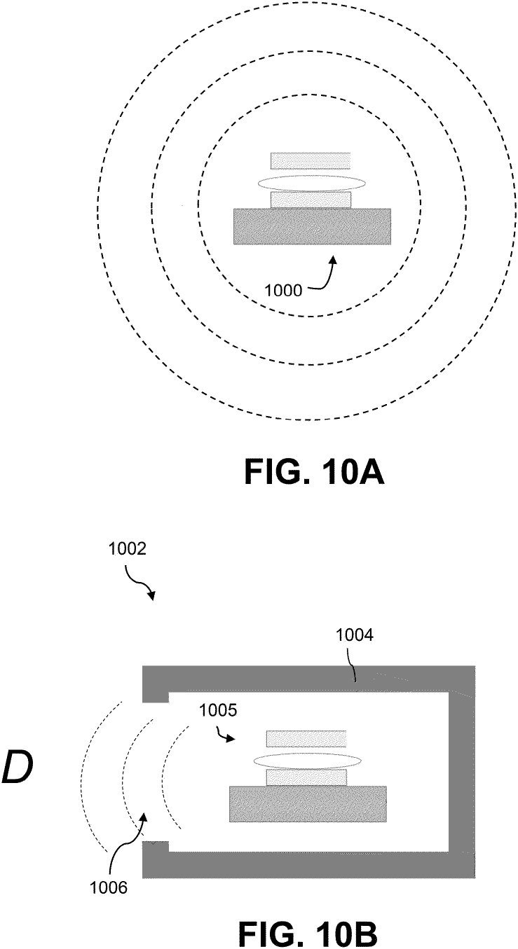

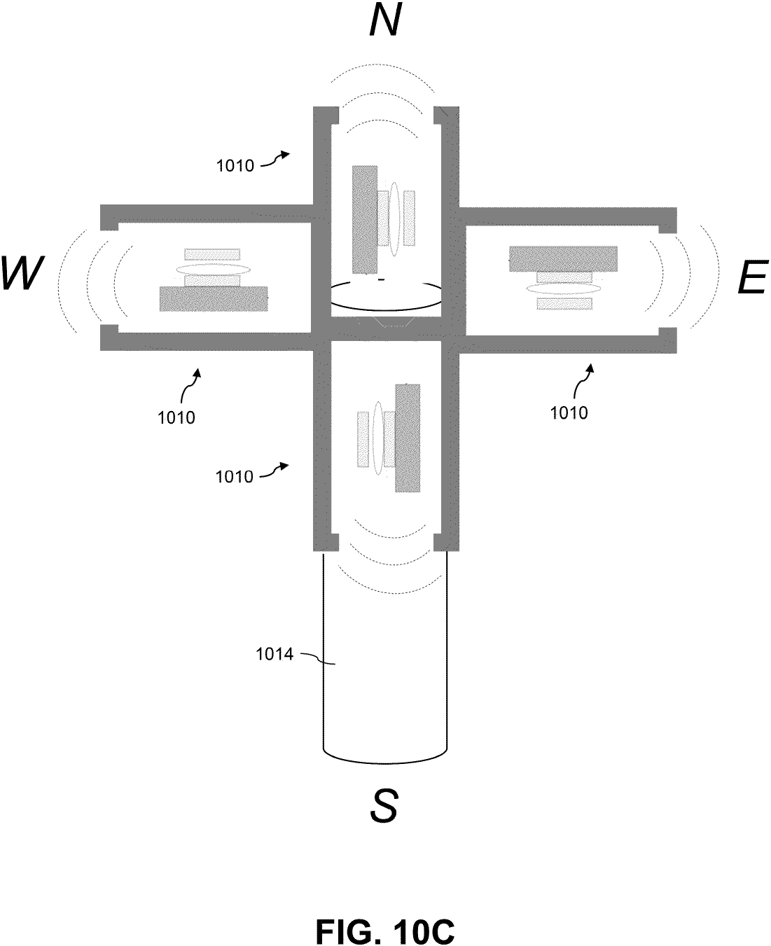

Each spin defect magnetometer can be configured in an “isotropic” configuration or in an “anisotropic” configuration. In the isotropic configuration, as shown in FIG. 10A, the magnetometer 1000 detects magnetic signals substantially uniformly from every direction, without a preferential sensing direction. Alternatively. in the anisotropic configuration, as shown in FIG. 10B, the magnetometer 1002 includes a magnetic shield 1004 (e.g., a mu-metal shield) having one or more apertures 1006. The magnetic shield 1004 blocks magnetic fields from directions besides direction D from interacting with sensing components 1005, such that the magnetometer 1002 is effectively “aimed” in the direction D and detects transit entities specifically in the direction D. The anisotropic configuration can be particularly useful when all-directional sensing is not necessary or desired. For example, in the case of a simple traffic-counting implementation, a single anisotropic magnetometer 1002 could be arranged so that the direction D cuts across a single lane of traffic, and vehicles in that single lane are detected and, in some implementations, classified.

In some implementations, multiple anisotropic magnetometers can be combined. For example, as shown in FIG. 10C, four anisotropic magnetometers 1010 have their apertures directed in four respective directions N, E, S, and W. The magnetometers 1010 can be mounted, for example, in an elevated position on a pole 1014 or other elevated stand (e.g., on a traffic signal mount). For example, in some implementations the pole 1014 or other elevated stand is positioned in the middle of a four-way intersection, and the magnetometers 1010 are aimed in each of the four directions of the intersection. The combination of signals from multiple anisotropic magnetometers amounts to effective pre-analysis filtering of spatial modes via physical configuration/arrangement, because directional information is known a priori based on the aimed direction of each anisotropic magnetometer 1010. In some implementations, this allows for more accurate transit entity location determination. In some implementations, this allows for a number of magnetometers in a given location to be reduced, because fewer magnetometers may be necessary to attain the same level of spatial reconstruction.

Once determined through spin defect magnetometry, locations of transit entities, trajectories of transit entities (e.g., their velocities and paths), and/or classifications of transit entities (collectively referred to as “transit entity analysis data”) can be transmitted to external systems and used to guide road operations. For example, as shown in FIG. 11, a local computer system 1100 is configured to transmit I2I messages 1102 to a traffic guiding system 1104. The traffic guiding system 1104 can include, for example, traffic lights and other switchable road infrastructure components. The I2I messages 1102 can be generated by the local computer system 1100 and/or by a remote computer system 1106 based on the transit entity analysis data. For example, if a high level of traffic is identified in a particular intersection using spin defect magnetometry, the I2I messages 1102 can include commands that cause the traffic guiding system 1104 to redirect traffic to other areas. In some implementations, traffic analysis is further based on magnetometry data provided to the remote computer system 1106 by other local computer systems 1120 that are coupled to other spin defect magnetometry devices.

The local computer system 1100 can additionally or alternatively be configured to transmit infrastructure-to-vehicle (I2V) messages 1112 to transit entities 1114 such as smart vehicles and mobile devices carried by pedestrians and bicycle riders. In some implementations, these I2V messages 1112 include the raw entity analysis data so that the transit entities 1114 can alter their behavior accordingly. For example, a smart vehicle having sensors that fail to detect another transit entity can be informed of the existence of the other transit entity by the I2V messages 1112 and take one or more actions in response, such as automatically braking to avoid colliding with the other transit entity. In some implementations, the local computer system 1100 is configured to itself perform danger detection analysis to predict imminent collisions or other dangerous situations in a vicinity of the local computer system 1100 based on the transit entity analysis data, and a corresponding warning can be sent to one or more transit entities as I2V messages 1112. As another example, in some implementations, magnetometers are positioned near parking spaces, and magnetic signal analysis includes an identification of which parking spaces are empty or full. Parking space occupation data can be sent to vehicles or software applications to guide parking.

In some implementations, certain analysis operations are performed at the local computer system 1100 and other analysis operations are performed at the remote computer system 1106. For example, analyses to be performed on a short time-scale (e.g., entity location and parameter determination, and danger detection analysis) can be performed at the local computer system 1100 for faster results and, accordingly, transmission of I2I and I2V messages 1102, 1112. Analysis that are less time-sensitive (e.g., analysis of traffic patterns over multiple days, weeks, or months) can be performed at the remote computer system 1106, which may have more computational resources (e.g., processing and/or storage resources) than has the local computer system 1100.

Other traffic analysis and control operations based on transit entity analysis data are also within the scope of this disclosure.

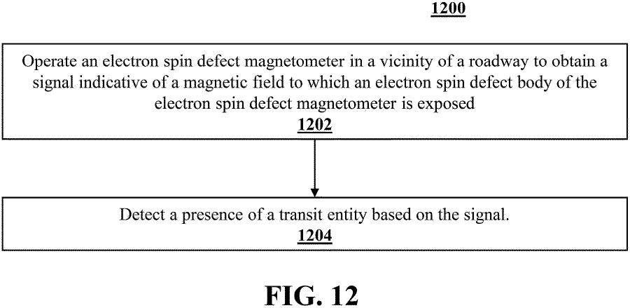

FIG. 12 illustrates an example traffic sensing method 1200 that can be performed in some implementations according to this disclosure. The method 1200, and methods related to and/or stemming from the method 1200, can be performed by a magnetometer computer device (e.g., magnetometer computer device 430), a local computer system (e.g., local computer system 512), or a remote computer system (e.g., remote computer system 514), or by any one or more of these computing systems in combination with one another. In the method 1200, an electron spin defect magnetometer is operated in a vicinity of a roadway to obtain a signal indicative of a magnetic field to which an electron spin defect body of the electron spin defect magnetometer is exposed (1202). For example, the electron spin defect body is illuminated with light, and photoluminescence emitted from the electron spin defect body is emitted, the photoluminescence providing the signal (e.g., as measured at a photodetector). A presence of a transit entity is detected based on the signal (1204). For example, the signal is processed (e.g., decomposed) to obtain a magnetic field signature, and the magnetic field signature is input into a machine learning model that produces an output indicative of the detection. Or, as another example, the signal itself can be input into the machine learning model.

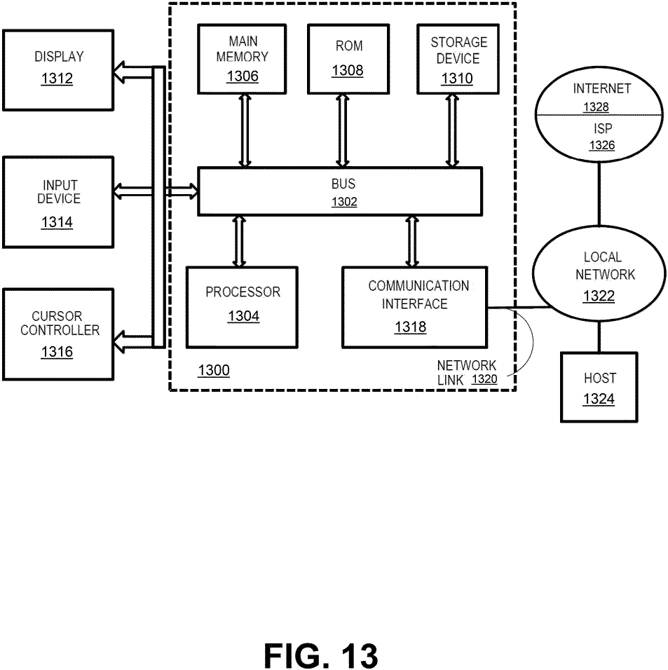

FIG. 13 illustrates a computer system 1300, such as the magnetometer computer device, the local computer system, or the remote computer system. In some implementations, the computer system 1300 is a special purpose computing device. The special-purpose computing device is hard-wired to perform the techniques or includes digital electronic devices such as one or more application-specific integrated circuits (ASICs) or field programmable gate arrays (FPGAs) that are persistently programmed to perform the techniques, or may include one or more general purpose hardware processors programmed to perform the techniques pursuant to program instructions in firmware, memory, other storage, or a combination. Such special-purpose computing devices may also combine custom hard-wired logic, ASICs, or FPGAs with custom programming to accomplish the techniques. In various embodiments, the special-purpose computing devices are desktop computer systems, portable computer systems, handheld devices, network devices or any other device that incorporates hard-wired and/or program logic to implement the techniques.

In some embodiments, the computer system 1300 includes a bus 1302 or other communication mechanism for communicating information, and one or more hardware processors 1304 coupled with a bus 1302 for processing information. The hardware processors 1304 are, for example, a general-purpose microprocessor. The computer system 1300 also includes a main memory 1306, such as a random-access memory (RAM) or other dynamic storage device, coupled to the bus 1302 for storing information and instructions to be executed by processors 1304. In some implementations, the main memory 1306 is used for storing temporary variables or other intermediate information during execution of instructions to be executed by the processors 1304. Such instructions, when stored in non-transitory storage media accessible to the processors 1304, render the computer system 1300 into a special-purpose machine that is customized to perform the operations specified in the instructions. The computer system 1300 can be “configured to” perform operations in the sense that the computer system 1300 is coupled to or includes non-transitory media storing instructions that, when executed by the processors 1304 of the computer system 1300, cause the processors 1304 to perform the operations.

In some implementations, the computer system 1300 further includes a read only memory (ROM) 1308 or other static storage device coupled to the bus 1302 for storing static information and instructions for the processors 1304. A storage device 1310, such as a magnetic disk, optical disk, solid-state drive, or three-dimensional cross point memory is provided and coupled to the bus 1302 for storing information and instructions.

In some implementations, the computer system 1300 is coupled via the bus 1302 to a display 1312, such as a cathode ray tube (CRT), a liquid crystal display (LCD), plasma display, light emitting diode (LED) display, or an organic light emitting diode (OLED) display for displaying information to a computer user. An input device 1314, including alphanumeric and other keys, is coupled to bus 1302 for communicating information and command selections to the processors 1304. Another type of user input device is a cursor controller 1316, such as a mouse, a trackball, a touch-enabled display, or cursor direction keys for communicating direction information and command selections to the processors 1304 and for controlling cursor movement on the display 1312. This input device typically has two degrees of freedom in two axes, a first axis (e.g., x-axis) and a second axis (e.g., y-axis), that allows the device to specify positions in a plane.

In some implementations, the techniques herein are performed by the computer system 1300 in response to the processors 1304 executing one or more sequences of one or more instructions contained in the main memory 1306. Such instructions are read into the main memory 1306 from another storage medium, such as the storage device 1310. Execution of the sequences of instructions contained in the main memory 1306 causes the processors 1304 to perform the process steps described herein. In alternative embodiments, hard-wired circuitry is used in place of or in combination with software instructions.

The term “storage media” as used herein refers to any non-transitory media that store data and/or instructions that cause a machine to operate in a specific fashion. Such storage media includes non-volatile media and/or volatile media. Non-volatile media includes, for example, optical disks, magnetic disks, solid-state drives, or three-dimensional cross point memory, such as the storage device 1310. Volatile media includes dynamic memory, such as the main memory 1306. Common forms of storage media include, for example, a floppy disk, a flexible disk, hard disk, solid-state drive, magnetic tape, or any other magnetic data storage medium, a CD-ROM, any other optical data storage medium, any physical medium with patterns of holes, a RAM, a PROM, and EPROM, a FLASH-EPROM, NV-RAM, or any other memory chip or cartridge.

Storage media is distinct from but can be used in conjunction with transmission media. Transmission media participates in transferring information between storage media. For example, transmission media includes coaxial cables, copper wire and fiber optics, including the wires that include the bus 1302. Transmission media can also take the form of acoustic or light waves, such as those generated during radio-wave and infrared data communications.

In some embodiments, various forms of media are involved in carrying one or more sequences of one or more instructions to the processors 1304 for execution. For example, the instructions are initially carried on a magnetic disk or solid-state drive of a remote computer. The remote computer loads the instructions into its dynamic memory and send the instructions as data in a signal over a network. A network device receives the signal and places the data on the bus 1302. The bus 1302 carries the data to the main memory 1206, from which processors 1304 retrieves and executes the instructions. The instructions received by the main memory 1306 may optionally be stored on the storage device 1210 either before or after execution by processors 1304.

The computer system 1300 also includes a communication interface 1318 coupled to the bus 1302. The communication interface 1318 provides a two-way data communication coupling to a network link 1320 that is connected to a local network 1322. For example, the communication interface 1318 is an integrated service digital network (ISDN) card, cable modem, satellite modem, or a modem to provide a data communication connection to a corresponding type of telephone line. As another example, the communication interface 1318 is a local area network (LAN) card to provide a data communication connection to a compatible LAN. In some implementations, wireless links are also implemented. In any such implementation, the communication interface 1318 sends and receives electrical, electromagnetic, or optical signals that carry digital data streams representing various types of information. For example, Bluetooth signals can be used.

The network link 1320 typically provides data communication through one or more networks to other data devices. For example, the network link 1320 provides a connection through the local network 1322 to a host computer 1324 or to a cloud data center or equipment operated by an Internet Service Provider (ISP) 1326. The ISP 1326 in turn provides data communication services through the world-wide packet data communication network now commonly referred to as the “Internet” 1328. The local network 1322 and Internet 1328 both use electrical, electromagnetic or optical signals that carry digital data streams. The signals through the various networks and the signals on the network link 1320 and through the communication interface 1318, which carry the digital data to and from the computer system 1300, are example forms of transmission media. In some embodiments, the network 1320 contains a computing system, e.g., a remote computing system as described above.

The computer system 1300 sends messages and receives data, including program code, through the network(s), the network link 1320, and the communication interface 1318. In some embodiments, the computer system 1300 receives code for processing. The received code is executed by the processors 1304 as it is received, and/or stored in storage device 1310, or other non-volatile storage for later execution.

In accordance with this description of computer systems, embodiments and functional operations described in this specification, such as signal processing and analysis operations and magnetometer control operations, can be implemented in digital electronic circuitry, or in computer software, firmware, or hardware, including the structures disclosed in this specification and their structural equivalents, or in combinations of one or more of them. Embodiments can be implemented as one or more computer program products, i.e., one or more modules of non-transient computer program instructions encoded on a non-transient computer readable medium for execution by, or to control the operation of, a data processing apparatus. The computer readable medium can be a machine-readable storage device, a machine-readable storage substrate, a memory device, a composition of matter effecting a machine-readable propagated signal, or a combination of one or more of them.

While this specification contains many specifics, these should not be construed as limitations on the scope of the disclosure or of what may be claimed, but rather as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are described as being performed in a particular order, this should not be understood as requiring that such operations be performed in the particular order disclosed, or that all disclosed operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products

A number of embodiments have been described. Nevertheless, it will be understood that various modifications may be made without departing from the spirit and scope of the invention. Accordingly, other embodiments are within the scope of the following claims.

What is claimed is:

1. A traffic monitoring system comprising:
an electron spin defect magnetometer in a vicinity of a roadway, the electron spin defect magnetometer configured to detect magnetic field signals induced by transit entities in the vicinity of the roadway,
wherein the electron spin defect magnetometer comprises
an electron spin defect body comprising a plurality of lattice point defects,
an optical source arranged to excite the plurality of lattice point defects, and
a photodetector arranged to receive photoluminescence emitted by the plurality of lattice point defects.

2. The traffic monitoring system of claim 1, wherein the electron spin defect magnetometer is fixed in an elevated position with respect to the roadway.

3. The traffic monitoring system of claim 1, comprising a computer system coupled to the electron spin defect magnetometer, the computer system configured to perform operations comprising:
receiving, from the electron spin defect magnetometer, a signal indicative of a magnetic field to which the electron spin defect magnetometer is exposed; and
detecting a presence of a transit entity based on the signal.

4. The traffic monitoring system of claim 3, wherein the signal comprises a signal of photoluminescence detected in the electron spin defect magnetometer.

5. The traffic monitoring system of claim 3, wherein the operations comprise determining, based on the signal, a magnetic field direction of the magnetic field to which the electron spin defect magnetometer is exposed.

6. The traffic monitoring system of claim 3, wherein the operations comprise identifying, based on the signal, at least one of a type of the transit entity, a size of the transit entity, or a trajectory of the transit entity.

7. The traffic monitoring system of claim 6, wherein the transit entity comprises a ground transportation vehicle or a pedestrian.

8. The traffic monitoring system of claim 6, wherein identifying at least one of the type, the size, or the trajectory of the transit entity comprises inputting the signal into a trained machine learning model that outputs an indication of at least one of the type, the size, or the trajectory.

9. The traffic monitoring system of claim 6, wherein identifying at least one of the type, the size, or the trajectory of the transit entity comprises:
extracting, from the signal, a magnetic field signature; and
comparing the magnetic field signature to a plurality of predefined magnetic field signatures.

10. The traffic monitoring system of claim 3, wherein the operations comprise filtering out a frequency component of the signal.

11. The traffic monitoring system of claim 3, wherein the computer system is located in the vicinity of the roadway.

12. The traffic monitoring system of claim 1, comprising:
a plurality of electron spin defect magnetometers in the vicinity of the roadway, including the electron spin defect magnetometer; and
a computer system configured to perform operations comprising:
receiving, from the plurality of electron spin defect magnetometers, a corresponding plurality of signals indicative of respective magnetic fields to which the electron spin defect magnetometers are exposed; and
determining a location of a transit entity based on signals from at least two electron spin defect magnetometers of the plurality of electron spin defect magnetometers.

13. The traffic monitoring system of claim 12, wherein determining the location of the transit entity comprises performing a triangulation process based on the signals from the at least two electron spin defect magnetometers.

14. The traffic monitoring system of claim 12, wherein the operations comprise:
extracting a first magnetic field signature from a first signal of the plurality of signals;
extracting a second magnetic field signature from a second signal of the plurality of signals; and
determining that the first magnetic field signature and the second magnetic field signature are caused by a same transit entity in the vicinity of the roadway.

15. The traffic monitoring system of claim 1, wherein the optical source is configured to excite the plurality of lattice point defects with light of a first wavelength that excites the plurality of lattice point defects from a ground state to an excited state, and
wherein the photoluminescence emitted by the plurality of lattice point defects comprises light of a second wavelength that is different from the first wavelength.

16. The traffic monitoring system of claim 1, wherein the electron spin defect magnetometer comprises a magnet configured to apply a magnetic field to the electron spin defect body.

17. The traffic monitoring system of claim 1, wherein the electron spin defect magnetometer comprises a microwave field transmitter configured to apply a microwave field to the electron spin defect body.

18. A method comprising:
operating an electron spin defect magnetometer in a vicinity of a roadway to obtain a signal indicative of a magnetic field to which an electron spin defect body of the electron spin defect magnetometer is exposed; and
detecting a presence of a transit entity based on the signal.

19. The method of claim 18, comprising:
determining, based on the signal, a magnetic field direction of the magnetic field.

20. The method of claim 18, comprising:
identifying, based on the signal, at least one of a type of the transit entity, a size of the transit entity, or a trajectory of the transit entity.

21. The method of claim 20, wherein the transit entity comprises a ground transportation vehicle or a pedestrian.

22. The method of claim 20, wherein identifying at least one of the type, the size, or the trajectory of the transit entity comprises inputting the signal into a trained machine learning model that outputs an indication of at least one of the type, the size, or the traj ectory.

23. The method of claim 20, wherein identifying at least one of the type, the size, or the trajectory of the transit entity comprises:
extracting, from the signal, a magnetic field signature; and
comparing the magnetic field signature to a plurality of predefined magnetic field signatures.

24. The method of claim 20, comprising filtering out a frequency component of the signal.

25. The method of claim 18, wherein the signal is a first signal, and wherein the method comprises:
operating a second electron spin defect magnetometer in the vicinity of the roadway to obtain a second signal indicative of a second magnetic field to which an electron spin defect body of the second electron spin defect magnetometer is exposed; and
determining a location of a transit entity based on the first signal and based on the second signal.

26. The method of claim 25, wherein determining the location of the transit entity comprises performing a triangulation process based on the first signal and based on the second signal.

27. The method of claim 25, comprising:
extracting a first magnetic field signature from the first signal;
extracting a second magnetic field signature from the second signal; and
determining that the first magnetic field signature and the second magnetic field signature are caused by a same transit entity in the vicinity of the roadway.

28. The method of claim 18, wherein operating the electron spin defect magnetometer comprises exciting a plurality of lattice point defects in the electron spin defect body.

29. The method of claim 18, wherein operating the electron spin defect magnetometer comprises measuring photoluminescence emitted by the electron spin defect body.
